(19) United States
(12) Patent Application Publication
(10) Pub. No.: US 2012/0087088 A1
(43) Pub. Date: Apr. 12, 2012

(54) MICROSCALE HEAT TRANSFER SYSTEMS

(75) Inventors: Jesse David Killion, Atlanta, GA (US); Seri Lee, Singapore (SG); Matthew Determan, Atlanta, GA (US); Scott W.C.H. Lee, Honolulu, HI (US); Abel Manual Siu Ho, Honolulu, HI (US)

(73) Assignee: PIPELINE MICRO, INC., Honolulu, HI (US)

(21) Appl. No.: 13/203,635

(22) PCT Filed: Mar. 1, 2010
(86) PCT No.: PCT/US10/25797

§ 371 Date: Dec. 12, 2011

Related U.S. Application Data
(63) Continuation-in-part of application No. 12/511,945, filed on Jul. 29, 2009.
(60) Provisional application No. 61/233,090, filed on Aug. 11, 2009.
(60) Provisional application No. 61/241,028, filed on Sep. 10, 2009.
(60) Provisional application No. 61/250,511, filed on Oct. 10, 2009.
(60) Provisional application No. 61/250,516, filed on Oct. 11, 2009.
(60) Provisional application No. 61/086,419, filed on Aug. 5, 2008.
(60) Provisional application No. 61/156,465, filed on Feb. 27, 2009.

(51) Int. Cl. H05K 7/20; F28D 11/06

(52) U.S. Cl. 361/697; 165/104.25; 361/700

(57) ABSTRACT

This disclosure concerns micro-scale heat transfer systems. Some systems relate to electronics cooling. As one example a microscale heat transfer system can comprise a microchannel heat exchanger defining a plurality of flow microchannels fluidicly coupled to each other by a plurality of cross-connect channels. The cross-connect channels can be spaced apart along a streamwise flow direction defined by the flow microchannels. Such a configuration of flow microchannels and cross-connect channels can enable the microchannel heat exchanger to stably vaporize a portion of a working fluid when the microchannel heat exchanger is thermally coupled to a heat source. Microscale heat transfer systems can also comprise a condenser fluidicly coupled to the microchannel heat exchanger and configured to condense the vaporized portion of the working fluid. A pump can circulate the working fluid between the microchannel heat exchanger and the condenser.

### CROSS REFERENCE TO RELATED APPLICATIONS

This application is a U.S. National Phase filing under 35 U.S.C. §371 of International Patent Application No. PCT/US2010/025797, filed Mar. 1, 2010, which is a continuation-in-part of U.S. Non-Provisional patent application Ser. No. 12/511,945, filed Jul. 29, 2009, and claims priority to and benefit of U.S. Provisional Patent Application No. 61/156,465, filed Feb. 27, 2009, U.S. Provisional Patent Application No. 61/233,090, filed Aug. 11, 2009, U.S. Provisional Patent Application No. 61/241,028, filed Sep. 10, 2009, U.S. Provisional Patent Application No. 61/250,511, filed Oct. 10, 2009, and U.S. Provisional Patent Application No. 61/250,516, filed Oct. 11, 2009. Each of the foregoing applications is incorporated herein in its entirety by this reference.

### FIELD

This application concerns micro-scale heat transfer systems, such as, for example, systems relating to electronics cooling, with cooling one or more electronic components mounted on an add-in card being but one example.

### BACKGROUND

Industrial processes, consumer goods, power generators and electronic components are but a few examples of sources of waste heat cooled by various cooling apparatus. For example, an upper threshold temperature corresponding to one or more measures of reliability for an electronic component (e.g., a semiconductor die defining one or more portions of an integrated circuit) can be specified. Such electronic components typically dissipate heat during operation, causing a temperature of the component to exceed a local ambient temperature, and in some instances, the upper threshold temperature. Conventionally, air-cooled heat sinks (or other cooling apparatus) have been placed in thermal contact with such components to improve rates of heat transfer from the component, and thereby maintain the component temperature at or below the upper threshold temperature during operation.

With reference to FIG. 1A, a plurality of electronic components 42, 44 and one or more substrates 46 can be electrically coupled together in an operable configuration 50. The operable configuration 50 can comprise a motherboard for a general purpose computing device, an add-in card for providing certain functionality to a computing device, a logic board for a specialty computing device, etc. As but one example, the operable configuration 50 can comprise a graphics card configured to provide graphics processing and output.

With reference to FIG. 1B, two or more electronic components 42, 44 can be mounted to one side of the substrate 46 using a variety of known techniques, such as, for example, soldering. In some operable configurations 50, the substrate 46 is a laminate substrate comprising at least one conductive layer and at least one corresponding dielectric layer. Such laminate substrates can comprise a plurality of conductive layers separated from adjacent conductive layers by one or more layers of a dielectric material. A printed circuit board (PCB) is but one example of such a laminate substrate.

During manufacturing, physical variation among individual units 50 can arise, despite being based on a selected design. For example, material properties can vary from lot to lot, individual substrates 46 are rarely if ever perfectly flat, a height Z₁, Z₂ measured from a surface of the substrate 46 adjacent a component 42, 44 to an upper surface of the component (or “z-height”) can vary from lot to lot, and even among units of a single lot. These and other physical variations can result in corresponding variations in relative z-height (e.g., Z₂-Z₁) between the components 42, 44. For example, even with a well-controlled manufacturing process, relative z-height between the components 42, 44 can vary among individually manufactured units of the operable configuration 50 by as much as +/−0.020 inches, or more.

Moreover, as electronic component designs evolve to achieve higher levels of performance, integrated circuits operate at higher frequencies, incorporate more transistors and occupy less physical space, resulting in higher operating power, higher heat flux or both. Although some component designs already exceed the cooling capability of conventional cooling systems, the trend toward increasing power and heat flux is expected to continue.

This relentless pursuit of new cooling techniques has traditionally yielded only incremental improvements in cooling capability. For example, a cooling device that delivers a temperature improvement compared to another cooling device of even just 3 or 4 degrees-Celsius (° C.) when dissipating about 150 Watts (W) (e.g., from a semiconductor die measuring about 1 cm²) has been considered a significantly improved cooling device.

Some have unsuccessfully attempted to use microchannel heat exchangers in combination with the latent heat of phase transition, and in particular, the latent heat of vaporization, (e.g., boiling) of certain coolants to cool such high powered (and high heat flux) devices. Unstable fluctuations in coolant flow rate, and corresponding fluctuations in coolant temperature and pressure, have been common deficiencies of prior attempts at using boiling through a microchannel heat sink to remove waste heat from, for example, an electronic component.

### SUMMARY

This disclosure concerns micro-scale heat transfer systems. Some systems relate to electronics cooling.

As one example, a microscale heat transfer system can comprise a microchannel heat exchanger defining a plurality of flow microchannels fluidicly coupled to each other by a plurality of cross-connect channels. The cross-connect channels can be spaced apart along a streamwise flow direction defined by the flow microchannels. Such a configuration of flow microchannels and cross-connect channels can enable the microchannel heat exchanger to stably vaporize a portion of a working fluid when the microchannel heat exchanger is thermally coupled to a heat source. Microscale heat transfer systems can also comprise a condenser fluidicly coupled to the microchannel heat exchanger and configured to condense the vaporized portion of the working fluid. A pump can circulate the working fluid between the microchannel heat exchanger and the condenser.

The microchannel heat exchanger and the condenser can comprise portions of an integrated subassembly. For example, a first plate can define opposed internal and external major surfaces. The internal major surface of the first plate can defines a heat sink region configured to receive a microchannel heat exchanger. A second plate can defining opposed internal and external major surfaces. The internal major surface of the second plate can define a lid region and a condenser region. The first plate and the second plate can be fixedly secured together in opposing alignment such that the respective internal major surfaces face each other. The microchannel heat exchanger can be disposed between the first plate and the second plate. The microchannel heat exchanger can be thermally coupled to the heat sink region. The lid region can overly the plurality of flow microchannels so as to define a flow boundary of the flow microchannels. The condenser region of the second plate and a corresponding, opposed region of the first plate can define at least one condenser flow channel.

The condenser region of the second plate can define a plurality of fins extending from the internal major surface of the second plate and being spaced from each other along a streamwise flow direction defined by the at least one condenser flow channel. In some instances, at least one of the plurality of extended surfaces is soldered to a corresponding portion of the internal surface of the first plate.

An integrated subassembly can further comprise a plurality of fins extending from the external major surface of the first plate, the second plate, or both. In some microscale heat transfer systems, the external major surface of the first plate defines a raised surface positioned substantially opposite the heat sink region defined by the internal major surface of the first plate. The microchannel heat exchanger can comprise a first microchannel heat exchanger and a second microchannel heat exchanger. The heat sink region can comprise a first heat sink region and a second heat sink region. The first heat sink region can be configured to receive the first microchannel heat sink, and the second heat sink region can be configured to receive the second microchannel heat sink

In some instances, the lid region comprises a first lid region and a second lid region. The first lid region can overly the first heat exchanger and the second lid region can overly the second microchannel heat exchanger.

The condenser region can comprise a first condenser region and a second condenser region. The first microchannel heat sink and the first condenser region can be fluidicly coupled to the second microchannel heat sink and the second condenser region in series. In other instances, the first microchannel heat sink and the first condenser region can be fluidicly coupled to the second microchannel heat sink and the second condenser region in parallel.

A pump housing manifold can define an internal chamber configured to receive a pump, an inlet opening and an outlet opening. The pump can be positioned at least partially within the internal chamber of the pump housing manifold. The pump can define a pump inlet and a pump outlet. The pump inlet can be fluidicly coupled to the inlet opening of the pump housing manifold and the pump outlet can be fluidicly coupled to the outlet opening of the pump housing manifold.

A flow cross-section of one or more of the flow microchannels can defines an aspect ratio greater than about 10:1, such as, for example, a 12:1 aspect ratio.

Add-in cards for computer systems are also disclosed. Some disclosed add-in cards comprise a substrate comprising a plurality of circuit portions, and at least one integrated circuit component electrically coupled to at least one of the circuit portions. In most instances, the integrated circuit component dissipates heat when operating. A cooling system for the add-in card can comprise a working fluid, an evaporator and a condenser. The evaporator can be positioned adjacent and thermally coupled to the integrated circuit component. The evaporator can define a plurality of cross-connected microchannels configured to stably vaporize a portion of the working fluid in response to heat dissipated by the component. The condenser can be fluidicly coupled to the evaporator, and supported, at least in part, by the substrate. A pump can fluidicly couple the evaporator and the condenser, so as to be operable to circulate the working fluid between the evaporator and the condenser

The condenser and the evaporator can comprise portions of an integrated subassembly comprising opposing first and second plates. For example, the evaporator can comprise a microchannel heat sink disposed between the first and second plates. A plurality of fins can extend outwardly of the first plate, the second plate, or both.

In some instances, the evaporator comprises a first evaporator and a second evaporator. The first evaporator and the second evaporator can be fluidicly coupled to each other in series. The first evaporator and the second evaporator can be fluidicly coupled to each other in parallel. In some instances, the condenser also comprises a plurality of fins extending outwardly. The add-in card can also comprise a shroud overlying the fins and a blower configured to deliver air over the fins. In addition, the evaporator, the condenser, the pump, the fins and the blower can, in some instances, fit within a 10½ inch, by 1⅜ inch, by 3¾ inch volume, when the evaporator, the condenser, the pump the fins and the blower are operatively positioned relative to each other and the integrated circuit component. The pump can be so positioned relative to the other components of the add-in card as to at least partially direct air from the blower among the fins.

A chassis member can overly and engage at least a portion of the substrate. The condenser can be fixedly attached to the chassis member such that the chassis supports the condenser. Accordingly, the condenser can at least partially supported by the substrate.

Methods of cooling electronic components are also disclosed. For example, a method of cooling an electronic component can comprise flowing a working fluid in a predominately liquid phase into a plurality of microchannels. Heat dissipated by the electronic component can be absorbed with the working fluid. In some instances, a portion of the working fluid evaporates within the microchannels. A volume of working fluid can flow from one of the microchannels to another of the microchannels at one or more streamwise positions along the microchannels. Such a flow can at least partially equalize a pressure among the microchannels at the streamwise positions. The evaporated working fluid can be condensed in a condenser. The act of condensing the evaporated working fluid in the condenser can comprises flowing air over a plurality of fins extending from a surface of the condenser.

In some instances, the electronic component comprises a first packaged integrated circuit die and a second packaged integrated circuit die. The plurality of microchannels can comprise a first plurality of microchannels positioned adjacent the first integrated circuit die and a second plurality of microchannels positioned adjacent the second integrated circuit die. The act of flowing working fluid from one of the microchannels to another of the microchannels can comprise flowing working fluid from one of the microchannels of the first plurality of microchannels to another of the microchannels of the first plurality of microchannels, and flowing working fluid from one of the microchannels of the second plurality of microchannels to another of the microchannels of the second plurality of microchannels. In some instances, the act of evaporating working fluid in the microchannels can comprise evaporating working fluid in the first plurality of microchannels. The act of evaporating working fluid in the microchannels can also comprise evaporating working fluid in the second plurality of microchannels.

The condenser can comprise a first condenser portion and a second condenser portion. The act of condensing the evaporated working fluid in the condenser can comprises condensing the evaporated working fluid evaporated in the first plurality of microchannels in the first condenser portion.

The foregoing and other features and advantages will become more apparent from the following detailed description, which proceeds with reference to the accompanying drawings.

### BRIEF DESCRIPTION OF THE DRAWINGS

FIG. 1A illustrates a plan view of a schematic of an operable configuration comprising first and second electronic components mounted to a substrate, with an add-in card being but one example.

FIG. 1B illustrates a side elevation view of the operable configuration shown in FIG. 1.

FIG. 1C illustrates a side elevation of a portion of the operable configuration shown in FIGS. 1A and 1B.

FIG. 2 illustrates a schematic diagram of one example of a cooling system as disclosed herein.

FIG. 3 contains a plot of performance of cooling systems as disclosed herein compared to performance of prior art cooling systems.

FIG. 4A shows an exploded isometric view of an assembly comprising one embodiment of a cooling system as disclosed herein, a graphics card and a chassis member.

FIG. 4B shows an isometric view of the cooling system shown in FIG. 4A.

FIG. 4C shows a bottom plan view of the cooling system shown in FIGS. 4A and 4B.

FIG. 5 shows an isometric view of a partially assembled second embodiment of a cooling system.

FIG. 6 shows an exploded isometric view of the partially assembled cooling system shown in FIG. 5.

FIG. 7 illustrates an exploded view of a partial pump-housing manifold and pump assembly. FIGS. 7A and 7B show portions of another pump-housing manifold.

FIGS. 8A, 8B and 8C illustrate various isometric views of one embodiment of a microchannel heat exchanger lid incorporating inlet and outlet couplers.

FIG. 9 shows a top plan view of an array of cross-connected microchannels in a microchannel heat sink substrate. FIG. 9A shows a portion of the array shown in FIG. 9.

FIG. 10 shows a top view, an end elevation view, a side elevation view and an isometric view of cross-connected microchannels.

FIGS. 11A and 11B are schematic illustrations of a working sample of a microchannel heat sink formed using a microdeformation technique.

FIGS. 12A and 12B are schematic illustrations of a working sample of a microchannel heat sink formed using a skiving technique.

FIG. 13 is an exploded view of a condenser.

FIG. 14 shows two schematic illustrations of possible condenser configurations.

FIG. 15 shows an exploded view of a condenser and heat sink assembly.

FIG. 16 shows an exploded view of a condenser comprising fins extending from an outer surface of the condenser.

FIG. 17 shows an isometric view of a compact cooling system as disclosed herein.

FIG. 18 shows an isometric view of an underside of the cooling system in FIG. 17.

FIG. 19 shows a tray, or chassis member, configured to support components of the cooling system shown in FIG. 17.

FIG. 20 shows an isometric view of an integrated heat-sink-and-condenser subassembly.

FIG. 21 shows an isometric view of an underside of the integrated heat-sink-and-condenser subassembly shown in FIG. 20.

FIG. 22 shows an isometric view a heat sink portion of the subassembly shown in FIG. 20.

FIG. 23 shows an isometric view of a condenser portion of the subassembly shown in FIG. 20.

FIG. 24 shows a top plan view of another embodiment of a condenser portion for a subassembly as shown in FIG. 20.

FIG. 25 shows an exploded view of a second embodiment of a cooling system.

FIG. 26 illustrates an exploded view of a portion of the assembly shown in FIG. 25.

FIG. 27 illustrates a heat sink sub-assembly.

FIG. 28 illustrates another heat sink sub-assembly.

FIG. 29 shows an exploded isometric view from below a condenser in the sub-assembly shown in FIG. 27.

FIG. 30 shows a pair of heat sink sub-assemblies.

FIG. 31 shows an exploded view of a cooling system comprising the heat sink sub-assemblies shown in FIG. 30.

FIG. 32 shows time-varying fluctuations of fluid pressure resulting from a stable, two-phase flow through a microchannel heat sink as disclosed herein.

FIG. 33 shows a graph of predicted heat sink temperature variation with microchannel aspect ratio for systems as disclosed herein.

FIG. 34 shows a graph of predicted pump back pressure variation with microchannel aspect ratio for systems as disclosed herein.

FIG. 35 shows a comparison plot of microchannel heat sink temperature rise above ambient temperature for a microchannel heat sink defining microchannels with an aspect ratio of 6:1 and a microchannel heat sink defining microchannels with an aspect ratio of 12:1, as disclosed herein.

### DETAILED DESCRIPTION

The following describes various principles related to microscale heat transfer systems by way of reference to exemplary systems. One or more of the disclosed principles can be incorporated in various system configurations to achieve various microscale heat transfer system characteristics. Systems relating to cooling one or more electronic components are merely examples of microscale heat transfer systems and are described below to illustrate aspects of the various principles disclosed herein.

### Overview

In one sense, microscale heat transfer systems can comprise a first heat exchanger configured to permit a working fluid to absorb heat from a heat source (e.g., by vaporizing), a second heat exchanger configured to permit the working fluid to reject the absorbed heat to an environmental medium (e.g., by condensing) and a pump configured to circulate the working fluid between the first and the second heat exchangers. In another sense, microscale heat transfer systems comprise methods relating to dissipating heat from a region of high heat flux across a low temperature gradient. Principles relating to such microscale heat transfer systems will now be described in connection with systems (also referred to herein as “cooling systems”) configured to cool one or more electronic components mounted to an add-in card.

Some cooling systems define an integrated cooling system sized to fit within a small, compact volume, such as, for example, within a physical form factor compatible with the PCIe Specification. For example, a maximum allowable thickness for some applications (including a printed circuit board thickness and a height of any components mounted to the circuit board) can be about 1.375 inches (e.g., a “double slot” PCIe card), and for other applications about 0.57 inches (e.g., a “single slot” PCIe card). Such cooling systems can comprise a self-contained, forced, two-phase fluid circuit as described more fully below. Additional aspects of cooling systems are also described.

Some cooling systems 100, 200, 300, 400 as described herein can fit within a volume measuring about 10½ inches, by about 1⅜ inches, by about 3¾ inches, and can cool first and second components that each dissipate about 150 Watts (W) continuously (300 W total), with about a 35 degree Celsius (° C.) temperature difference between a maximum component temperature (e.g., a case temperature) and an environmental air temperature. Other cooling systems (including some working embodiments of such cooling systems) can sufficiently cool first and second components that each dissipate about 200 W (400 W total). Some disclosed cooling systems can simultaneously accommodate z-height variations between components exceeding 0.020 inches, such as up to about 0.030 inches.

As used herein, “microchannel” means a channel having at least one major dimension (e.g., a channel width) measuring less than about 1 mm, such as, for example, about 0.1 mm, or several tenths of millimeters.

As used herein, “fluidic” means of or pertaining to a fluid (e.g., a gas, a liquid, a mixture of a liquid phase and a gas phase, etc.). Thus, two regions that are “fluidicly coupled” are so coupled to each other as to permit a fluid to flow from one of the regions to the other region in response to a pressure gradient between the regions.

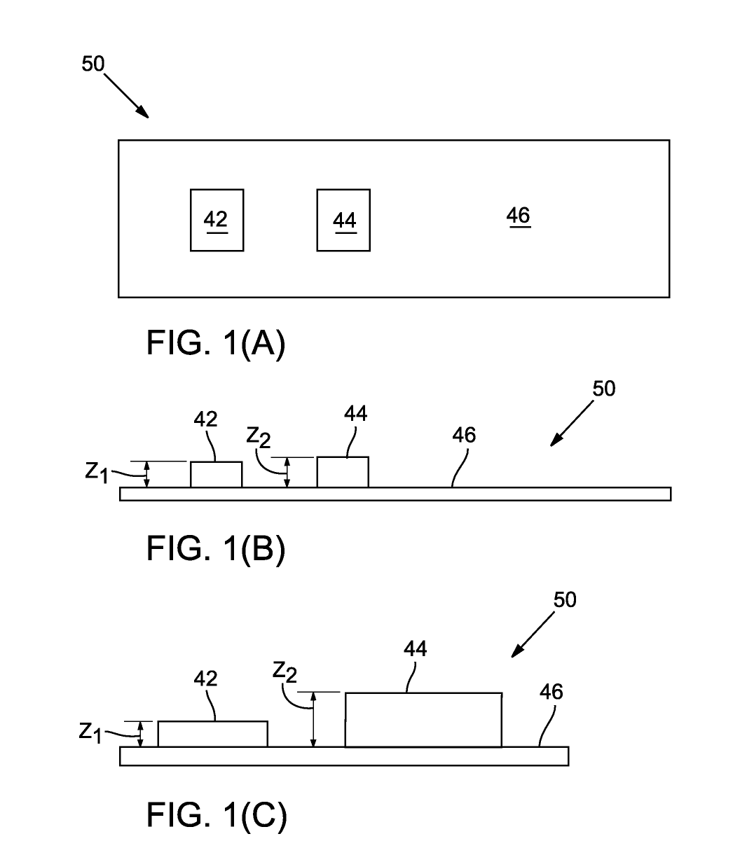

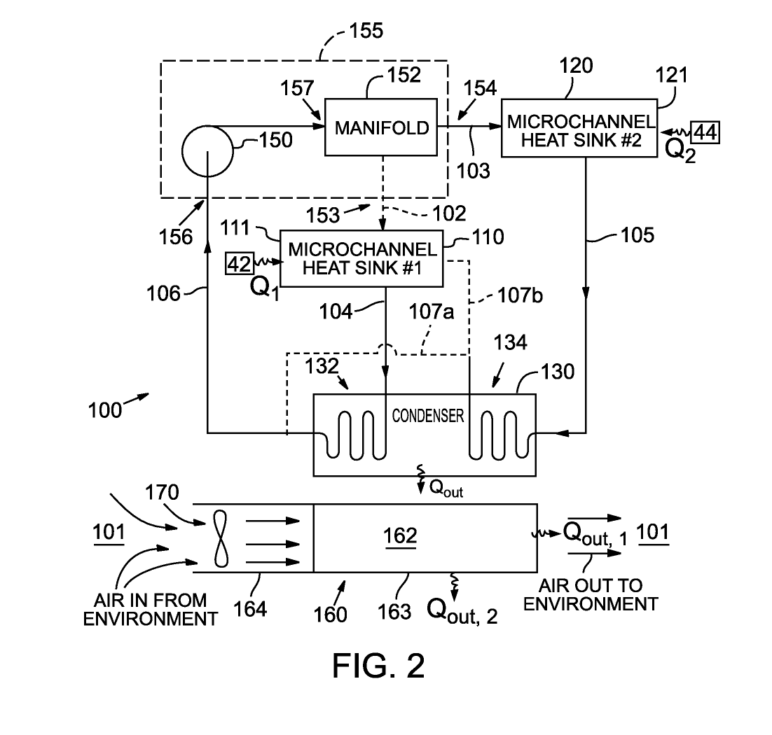

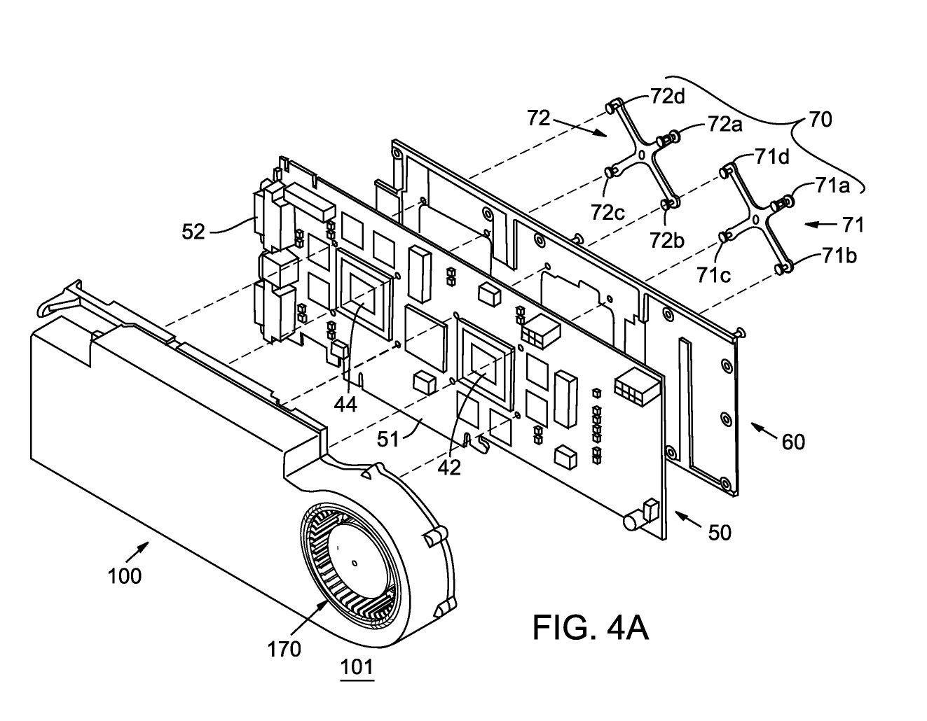

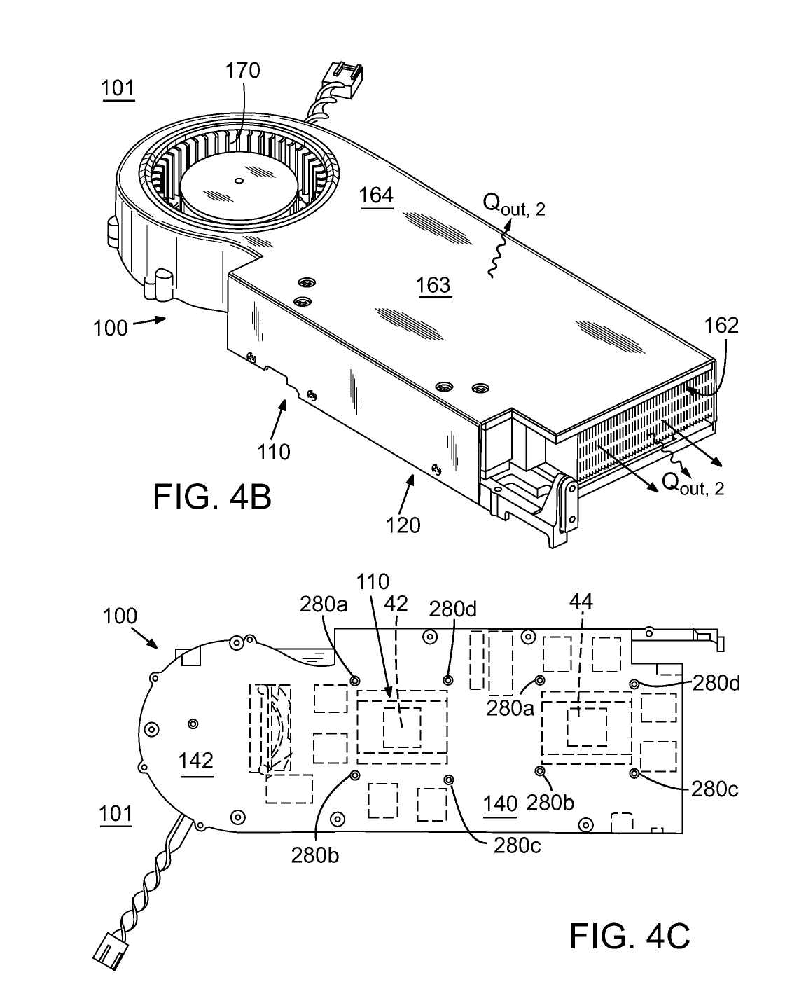

As used herein, the terms “working fluid” and “coolant” are interchangeable. Referring to FIG. 2, a cooling system 100 can comprise one or more microchannel heat sinks 110, 120 (e.g., first heat exchangers, also referred to as “evaporators”) configured to cool one or more respective electronic components 42, 44 (FIG. 1, FIG. 4A), as by facilitating the absorption of heat Q₁, Q₂ dissipated by the respective electronic components, by a working fluid (not shown) passing through the heat sinks. In some systems, a liquid phase or a saturated mixture of liquid and vapor can enter the evaporators 110, 120. As heat Q₁, Q₂ is transferred to the working fluid, the liquid portion can vaporize in the respective evaporator 110, 120. Since the latent heat of vaporization (or condensation) typically is much greater than the specific heat of a given fluid, more heat can usually be absorbed or rejected by the fluid through a change of phase than by merely a change in temperature.

The system 100 can also comprise one or more condensers 130 (e.g., a second heat exchanger) configured to facilitate the rejection of heat Q₁, Q₂ absorbed by the working fluid in the respective evaporators 110, 120. In some systems, a vapor-phase or a saturated mixture of liquid and vapor can enter the condenser 130 after passing through the evaporators 110, 120. As heat Qₒᵤₜ is transferred from the working fluid and the condenser 130, a vapor portion of the working fluid can condense.

A pump 150 can circulate a working fluid among the heat sinks 110, 120 and the condenser 130. The pump 150 can be fluidicly coupled to a manifold 152 to distribute the working fluid among various components of the fluid circuit defined by the cooling system 100. As described more fully below, a housing 155 for the pump 150 can define the manifold 152 (also referred to herein as a “pump-housing manifold”).

The condenser 130 can be configured to reject the absorbed heat Q_{1,out}, Q_{2,out} to an environmental fluid (e.g., air) 101 from a local environment. For example, as described more fully below, a cooler 160 can be thermally coupled to the condenser 130 to remove the absorbed heat from the fluid. In such an embodiment, an air-cooled heat sink 162 can be thermally coupled to the condenser 130. In some instances, the condenser 130 supports extended heat transfer surfaces, or fins, positioned on an external surface of the condenser, providing an integrated condenser and heat sink subassembly (e.g., a unitary construction).

Such accumulation, carrying and rejection of heat can improve cooling of (e.g., rates of heat transfer from) electronic components as compared to conventional cooling systems having been used to cool electronic components. Improved rates of heat transfer can allow electronic components 42, 44 to dissipate more power for a given temperature difference between the component and the environment, allowing the electronic components to achieve higher levels of performance without modifying the environment (e.g., reducing the environmental temperature) or modifying the specified upper threshold temperature (e.g., increasing the upper threshold temperature) of the electronic component.

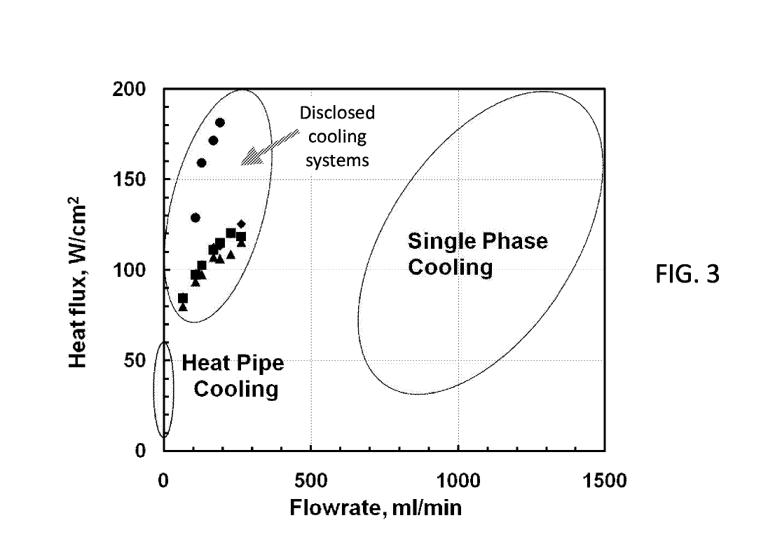

As FIG. 3 indicates, disclosed cooling systems can cool a heat flux in excess of about 70 Watts per square centimeter (W/cm²) and up to about 200 W/cm², such as, for example, between about 80 W/cm² and about 190 W/cm², with a working fluid flow rate of less than about 400 milliliters per minute (ml/min), such as, for example, between about 75 ml/min and about 300 ml/min. Disclosed cooling systems incorporate a pump configured to distribute the working fluid among the various system components.

By contrast, passive two-phase systems (also referred to as “heat pipe cooling” systems or “thermosyphon” systems) are able to cool only up to about 60 W/cm². Such passive two-phase systems rely on surface-tension forces and boiling to “pump” a working fluid through the system.

Although some single-phase cooling systems might be capable of cooling up to about 200 W/cm², such single-phase cooling systems require very large flow rates of working fluid (e.g., between about 700 ml/min and about 1500 ml/min) and correspondingly large components configured to accommodate large volumes of coolant. When combined into an operable system, such large, bulky components are incapable of fitting within a compact volume, such as that defined by the PCIe specification. For example, known single-phase cooling systems require a large, remote heat exchanger, or radiator (much like an automobile radiator), spaced from the electronic component being cooled. Although such a radiator can often be placed on a rear panel of a computer system, or placed externally of an enclosure housing the component(s) being cooled, not all components of known single-phase cooling systems are capable of being mounted to an add-in card, which stands in stark contrast to disclosed systems.

In contrast to known passive two-phase cooling systems and known single-phase cooling systems, disclosed cooling systems 100, 200, 300, 400 are capable of dissipating high heat fluxes (as noted above and shown in FIG. 3), while still being integrated into a compact system that fits within a small volume (such as, for example, within a volume measuring about 10½ inches by about 1⅜ inches about 3¾ inches. Such compact cooling systems are made possible, in part, because disclosed systems require substantially less working fluid than single-phase systems, and can cool high heat fluxes, in part, because the pumped (or forced) fluid circuit can circulate working fluid through the cooling system at higher flow rates than a thermosyphon can circulate coolant.

### Overview of Compact Cooling Systems

Although specific embodiments of compact, integrated cooling systems and related apparatus configured to fit within a small volume are described in substantial detail below, a brief overview of such systems is provided with reference to FIGS. 4A, 4B and 4C. The exploded view shown in FIG. 4A illustrates a compact embodiment of the cooling system 100 (described above, generally, with reference to FIG. 2), a computer add-in card 50, a support member (or chassis member) 60, and retention clips 71, 72 configured to retain the laminated assembly of the cooling system, card and support member by the cooling system 100 and the retainer 70 together.

The illustrated add-in card 50 can be a high performance graphics card configured according to the PCIe Specification. The card 50 can comprise a printed circuit board (PCB) substrate 46 having an edge connector 51 and a rear-panel interface region 52 comprising plural connectors configured to interface with one or more external accessories (not shown). The card 50 can have two graphics processing units (GPUs) 42, 44 mounted to the substrate 46. The PCB can define one or more electrical circuit portions, and each of the GPUs 42, 44 can be electrically coupled to respective electrical circuit portions. The edge connector 51 can be configured according to the PCIe Specification and can convey electrical signals and power to the circuit portions within the PCB.

As indicated by the schematic illustration of the cooling system 100 shown in FIG. 2, the system shown in FIGS. 4A, 4B and 4C comprises first and second microchannel heat sinks 110, 120 fluidicly coupled to a condenser 130. A heat exchanger 160 (e.g., the air-cooled heat sink 162) facilitates heat transfer Qₒᵤₜ from the condenser 130 to the environment 101. A centrifugal blower or pump (or other fluid-moving device) 170 can be configured to cause (e.g., urge) the environmental fluid to pass through the heat sink 162A, and a portion Q_{out,1} of the heat Qₒᵤₜ can be rejected to the environmental fluid (e.g., air as it passes among the fins of the heat sink 162). A shroud, or duct, 164 defines a channel, or passageway or conduit, configured to direct air among the extended surfaces (fins) of the heat sink 162 from the blower impeller 170. Without the duct 164, a portion of the airflow emitted by the blower 170 might otherwise circumvent (e.g., bypass) the channels defined among fins of the heat sink 162. In some instances, a plastic shroud can form the duct 164.

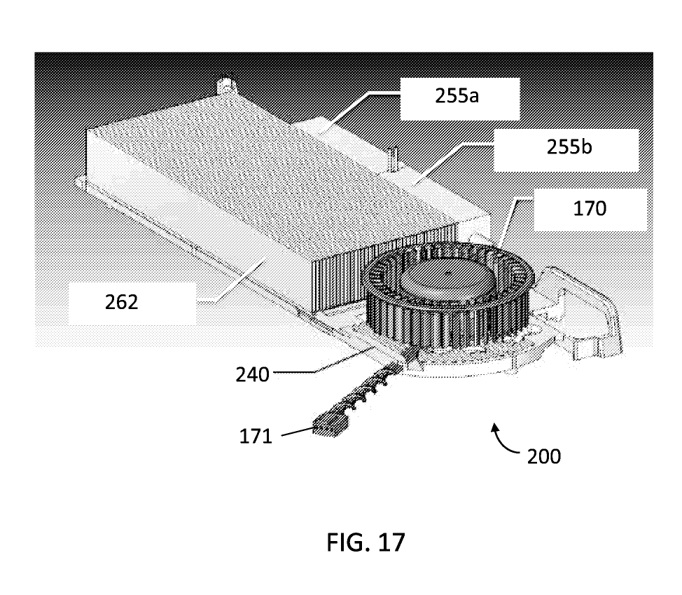

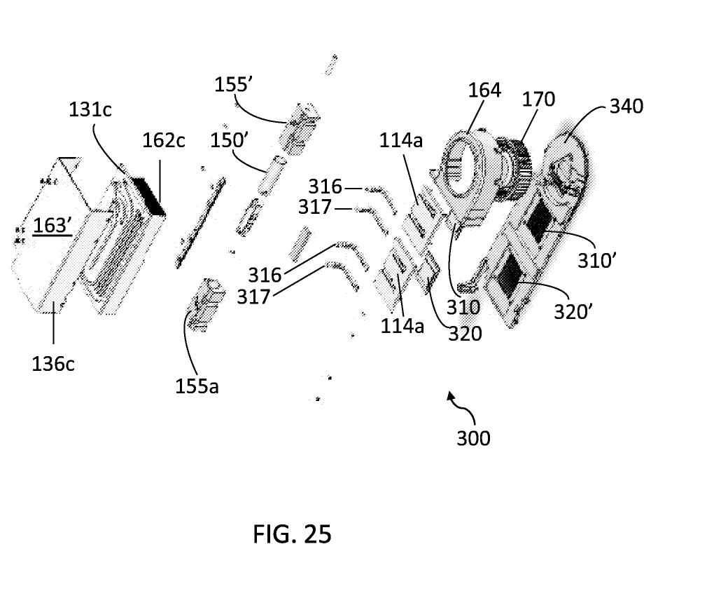

The system 100 shown in FIGS. 4A, 4B and 4C also comprises an integrated pump-and-manifold subassembly 155 (not visible in FIGS. 4A, 4B or 4C, as it is covered by the duct 164 and shroud 163) configured to circulate the working fluid among the heat sinks 110, 120 and the condenser 130. The system 100 shown in FIGS. 4A, 4B and 4C can comprise a “closed system,” meaning that during operation, a mass of the working fluid within the system 100 remains constant or at least substantially constant. The position of the pump-and-manifold subassembly 155 is similar to the position of the pump manifold subassemblies 155′ and 255 illustrated in FIGS. 17 and 25, respectively.

With further reference to FIGS. 2, 4A, 4B and 4C, and as noted above, the pump 150 (not shown) delivers the working fluid (not shown) to a manifold 152 (not shown) configured to distribute the working fluid to each heat sink 110, 120 (FIG. 4C). Respective conduits, or fluid connections, 102, 103 (not shown) fluidicly couple corresponding outlets of the manifold 152 with corresponding heat sinks 110, 120. Each of the heat sinks 110, 120 can be fluidicly coupled to respective condenser portions 132, 134 (not shown) defined by the condenser 130 by respective conduits, or fluid connections, 104, 105. A conduit, or fluid connection, 106 can fluidicly couple the condenser portions 132, 134 to an inlet to the pump 150.

As noted above, each of the conduits, or fluid connections, 102, 103, 104, 105, 106, 107a, 107b can be configured to convey the working fluid (in a vapor phase, a liquid phase, or a saturated mixture of both) between respective system components 110, 120, 130, 150, 152, 155. Such conduits, or fluid connections, can comprise conventional tubes, or pipes, formed from, for example, an alloy of aluminum. In other embodiments, such conduits, or fluid connections, can comprise adjoining openings, as described more fully below with regard to systems comprising one or more manifolds.

With reference to FIG. 2, as indicated by the dashed lines 102 and 107a, the heat sink 120 and condenser portion 134 can be fluidicly coupled in parallel to the heat sink 110 and condenser portion 132. Alternatively, as indicated by the dashed line 107b, the heat sink 120 and the condenser portion 134 can be fluidicly coupled in series to the heat sink 110 and the condenser portion 132 (as by eliminating the connection 102 between the pump 150 and the heat sink 110). Each of the parallel and series configurations just described in connection with the schematic illustration in FIG. 2 can be incorporated in the system embodiment 100 shown in FIGS. 4A, 4B and 4C. Fluidicly coupling the microchannel heat sinks 110, 120 in parallel, as just described, can in some instances supply lower-temperature working fluid to one of the microchannel heat sinks than if the heat sinks were fluidly coupled in series. For example, the heat sink that would otherwise receive pre-heated working fluid if the heat sinks were fluidly coupled in series can receive unheated working fluid when the heat sinks are fluidicly coupled in parallel.

Applicants discovered that, in some instances, such as in applications providing limited physical volume for the cooling system 100, such as computer add-in cards (e.g., graphics cards), heat exchange between the condenser 130 and the environment (e.g., “air-side heat exchange”) can limit the overall performance of the cooling system 100. Applicants also discovered that the effect of such a performance “bottleneck” can be mitigated, at least in part, by providing as much “air-side” heat transfer surface as possible given volume constraints imposed on the cooling system 100. One approach to improving airside heat transfer in a system 100 is to provide fins that are a long as a possible where fitting within the limited physical volume.

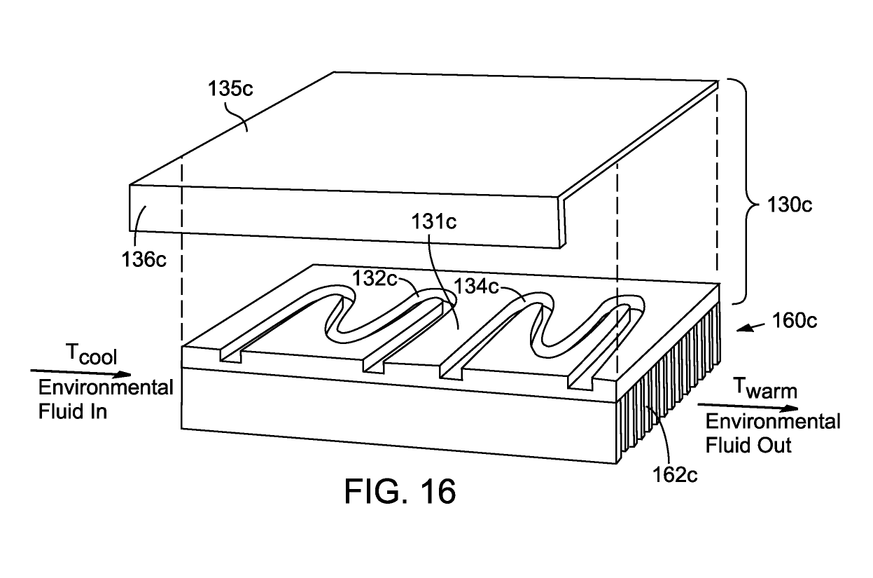

At least in some instances, substantially greater fin surface area can be achieved if the condenser 130 and the heat sink 162 are combined, such that fins extend from the condenser body (as in FIGS. 16 and 17), as opposed to thermally coupling a separate heat sink 162 (e.g., a base member having fins extending therefrom) to the condenser (as in FIG. 15).

With reference to FIG. 4A, the cooling system 100 can be retained in close proximity to the add-in card 50. For example, the retaining clips 71, 72 can so engage features 280a-d (FIG. 4C) extending from each of the heat sinks 110, 120 and through the PCB 46 and chassis member 140, 142, 143 as to urge the add-in card in compression between the chassis member and cooling system 100. For example, couplers 71a-d can engage respective features 280a-d extending from the heat sink 110, and couplers 72a-d can engage respective features 280a-d extending from the heat sink 120. Each heat sink 110, 120 can comprise a portion defining a mating surface that extends through an opening in the chassis member, such that each respective mating surface is in direct contact with, or positioned adjacent to, a corresponding electronic component 42, 44, thereby thermally coupling each heat sink to a respective component 42, 44.

These and other features and principles concerning cooling systems are described more fully below in connection with specific embodiments relating to cooling electronic components, such as graphics components mounted to a graphics card.

### Pump and Manifold

Manifolds and pump-housing manifolds will now be described. As indicated in FIG. 2, the cooling system 100 comprises a pump-housing manifold 155 configured to house the pump 150 and to distribute working fluid to the respective heat sinks 110, 120.

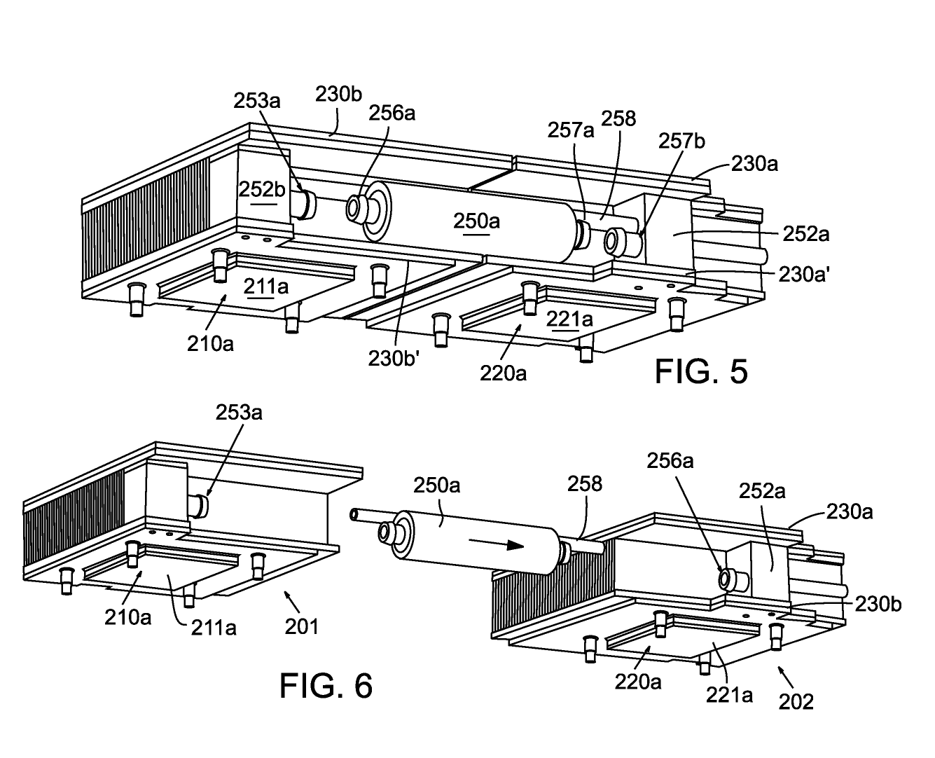

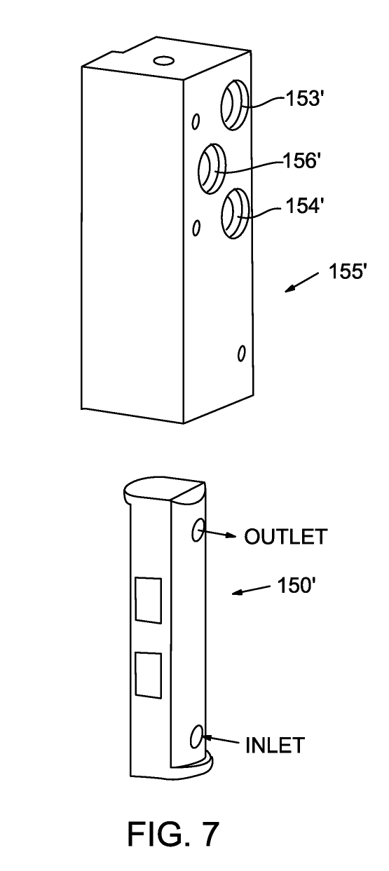

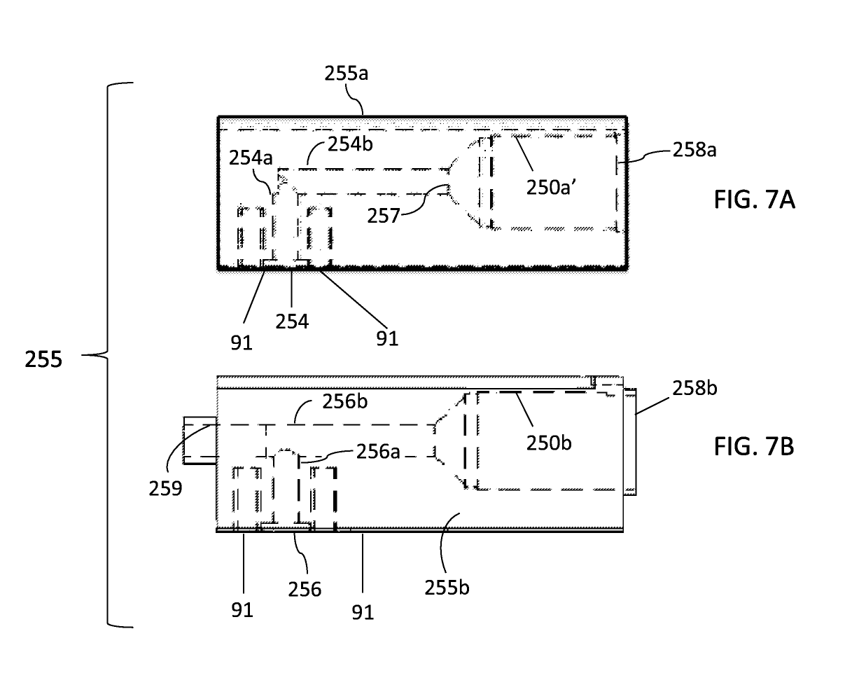

With reference to FIGS. 5 and 6, the pump 250a can urge a working fluid (e.g., can cause the working fluid to circulate) among various portions of a cooling system. One or more manifolds 252a, 252b (and/or one or more pump-housing manifolds 155′(FIG. 7)) can be used to distribute a working fluid among one or more other portions of the cooling system so as to eliminate or reduce conventional piping, or tubing, from conduits (or fluid connections) within the cooling system. Such a manifold 252a, 252b can comprise a copper block defining a plurality of internal passageways configured as one or more plenums or flow paths within the block. For example, one or more intersecting bores (e.g., drilled holes) in such a block can define such flow channels in the manifold 252a.

Referring still to FIGS. 5 and 6, the pump 250a can be fluidicly coupled to respective microchannel heat sinks 210a, 220a of the heat sink assemblies 201 and 202 and condensers 230a, 230a′, 230b, 230b′ by way of manifolds 252a, 252b. For example, a pump outlet 257a can be fluidicly coupled (e.g., by a tube) to an inlet coupler 257b of the manifold 252a. The manifold 252a defines internal passages (not shown) that are configured to distribute a working fluid from a manifold inlet 256a defined by the inlet coupler 257b to a manifold outlet (not shown) that is in turn fluidicly coupled to the heat sink 220a. An outlet (not shown) from the heat sink 220a can be fluidicly coupled to the condenser 230a′, as well as the manifold 252a such that a portion of the working fluid that has passed through the heat sink flows through the manifold 252a and into a second condenser 230a.

In a similar fashion, the manifold 252b fluidicly couples the heat sink 210a to the condensers 230b, 230b′. The outlets (not shown) of the condensers 230b, 230b′ are fluidicly coupled to the manifold outlet 253a, which in turn is fluidicly coupled to an inlet 256a to the pump 250a. Thus, the pump 250a and the manifolds 252a, 252b are configured to circulate working fluid among the illustrated heat sinks and condensers through a closed fluid loop.

Referring now to FIG. 7, a portion of a pump-housing manifold 155′ and a pump 150′ are illustrated. The housing 155′ defines a pump receiving opening (not shown) configured to receive a portion of the pump 150′, such that the housing 155′ overlies the pump. The housing 155′ can also define one or more internal chambers (e.g., diffusers) (not shown) that together form a manifold being integral with the housing, thereby forming a pump-housing manifold. An outlet an inlet, or both, of the pump can be fluidicly coupled to one or more of the internal chambers.

The pump-housing manifold can define internal passageways (not shown) configured to convey a working fluid such that the pump inlet is fluidicly coupled to the inlet to the pump-housing manifold 155′, and the pump outlet is fluidicly coupled to the pump-housing manifold outlets 153′ and 154′.

Such a pump-housing-manifold 155′ can distribute the working fluid from one or more inlets 156′ (156 in FIG. 2) among various outlets 153′, 154′. For example, a first outlet 153′ from the pump-housing manifold 155′ and a first microchannel heat sink can be fluidicly coupled by a first conduit (in some instances a length of piping, or tubing), and a second outlet 154′ from the pump-housing manifold 155′ and a second microchannel heat sink can be fluidicly coupled by a second conduit.

Although two outlets 153′, 154′ from the pump-housing manifold 155′ are shown in FIG. 7, pump-housing manifolds having more or fewer than two outlets are contemplated and fall within the scope of the present disclosure. For example, some embodiments of cooling systems comprise three, four or more microchannel heat sinks fluidicly coupled to a single pump-housing manifold. In other embodiments, more than one outlet can convey working fluid from the pump-housing manifold to a given heat sink As described more fully below, some pump-housing manifolds have a single outlet and a single inlet (as can be the case when the heat sinks 110, 120 are fluidicly coupled in series).

The pump 150′ can be sized to provide sufficient head to circulate the working fluid throughout a cooling system. In some instances, such as when a temperature of the working fluid is near the fluid's phase-transition temperature, even a slight drop in pressure can cause a portion of the fluid to vaporize (or cavitate). Some pumps are more susceptible to such localized vaporization, or cavitation, than other pumps. As a class, positive displacement pumps (e.g., some piezoelectric pumps, reciprocating piston pumps and gear pumps) generally do not suffer from such localized vaporization. In some instances, the pump 150′ can comprise a pump comprising a reciprocating piston that urges against a portion of the working fluid adjacent the piston along each stroke of the piston as it reciprocates. In some working embodiments, commercially available, linear-electromagnetic pumps have been used.

Referring now to FIGS. 7A and 7B, a two-piece pump-housing manifold 255 is illustrated. The manifold 255 has a pump outlet portion 255a and a pump inlet portion 255b. The outlet portion 255a defines an interior chamber 250a′ sized to receive an outlet end of a pump similar to the pump 150′ shown in FIG. 7. The chamber 250a′ is configured to be compatible with a pump having a pump outlet positioned at an end of the pump, rather than on a sidewall of the pump as shown in FIG. 7. For example, the outlet portion 255a defines a manifold inlet 257 (157 in FIG. 2) positioned at an end of the chamber 250a′. The outlet portion 255a defines a manifold outlet 254 forming a recessed opening, or bore, 254a intersecting a transversely oriented bore 254b defining the manifold inlet 257. The intersecting bores 254a, 254b fluidicly couple the manifold inlet 257 and the manifold outlet 254.

The chamber 250a′ is recessed from an end of the illustrated outlet portion 255a and extends a depth into the outlet portion by a distance measuring about one-half of a length of a corresponding pump. The chamber also defines a recessed portion 258a extending around a perimeter of (e.g., circumferentially around) an opening to the chamber 250a. The recessed portion 258a is configured to receive a shoulder 258b (FIG. 7B) extending from the inlet portion 250b of the pump-housing manifold 255.

The illustrated inlet portion 250b defines a recessed chamber 250b configured to receive an inlet end of a corresponding pump (not shown). The inlet portion 255b also defines a manifold inlet 256 configured to receive a working fluid from a condenser (e.g., a condenser in the system 200, shown in FIGS. 17 through 24). A recessed opening, or bore, 256a extends inwardly of the inlet 256 and is transversely intersected by a bore 256b extending to and opening into the chamber 250b. Fluidicly coupled to the bore 256a is a fill tube 259. The fill tube 259 can be used to charge an assembled cooling system with a working fluid. For example, once a cooling system has been assembled, working fluid can be supplied to the fill tube, and condensable gasses (e.g., air) can be bled from the system using known techniques. Once a desired volume, or mass, of working fluid has been supplied to the cooling system, the fill tube 259 can be sealed.

Each of the portions 255a, 255b can define respective pairs of recessed openings 91 (e.g., threaded openings) configured to secure an assembled pump-housing manifold 255 to respective components of an assembled cooling system. In some instances, threaded fasteners, such as screws, can threadably engage the openings 91.

Manifolds as described above can decrease chances of leaking, improve structural integrity of the system and reduce the volume occupied by a cooling system (e.g., can allow a cooling system to fit within a smaller “packaging footprint”). In addition, such manifolds can define one or more faces that can provide a sufficiently large surface for joining (e.g., soldering, brazing or welding) conventional fluid conduit to the manifold inlet(s) and/or outlet(s).

### Microchannel Heat Sinks

### Overview

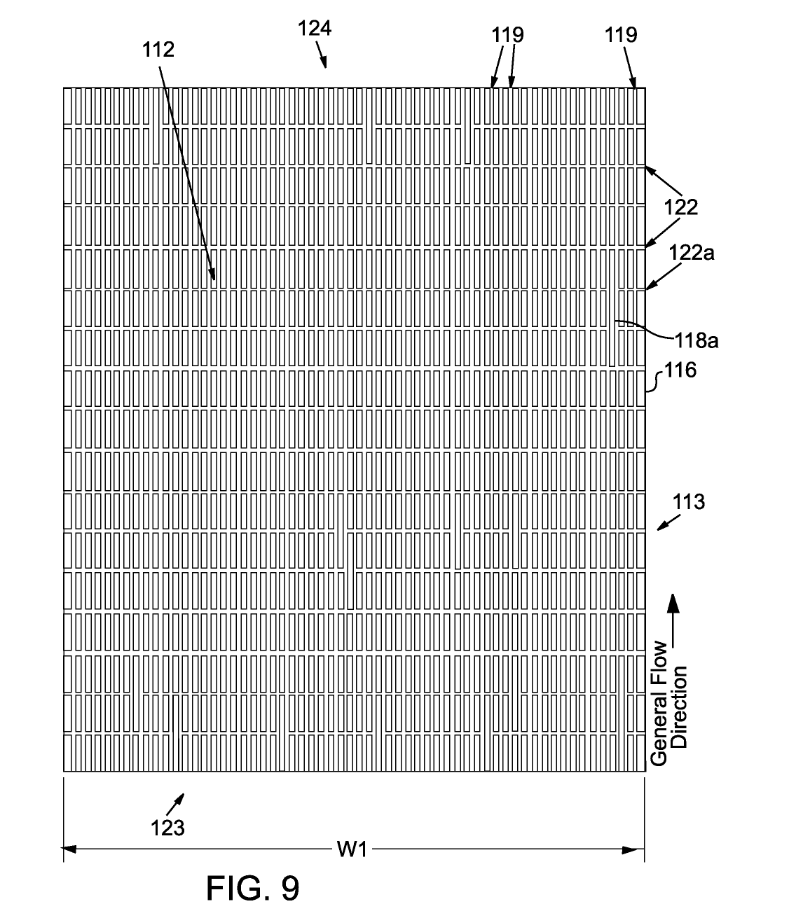

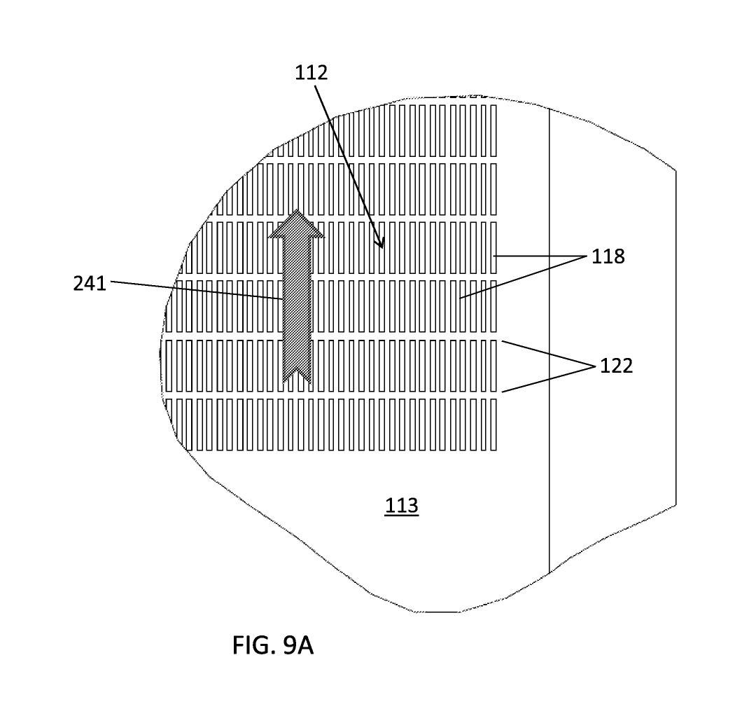

Microchannel heat sink configurations will now be described with reference to FIGS. 2, and 8A through 12B in the accompanying drawings. In one sense, a microchannel heat exchanger 110, 120 (FIG. 2) can comprise three portions: (1) an external heat transfer surface 111, 111a, 221a (FIGS. 2, 5, 6 and 10) through which heat Q₁, Q₂ (FIG. 2) can be exchanged with an external fluid or body (such as, for example, an electronic component 42, 44 (FIG. 2)); (2) an internal heat transfer surface 112, 112A, 112b (FIGS. 9, 9A, 10, 11A and 12A) through which the heat from the external fluid or body can pass into and be exchanged with a working fluid; and (3) the working fluid (not shown) within the heat exchanger. As shown in FIGS. 5, 6 and 10, an external heat transfer surface 111a, 221a can define a flat surface configured to mate with a corresponding flat surface of an electronic component 42, 44 when the respective microchannel heat exchanger 110, 120, 110a, 120a is operatively positioned.

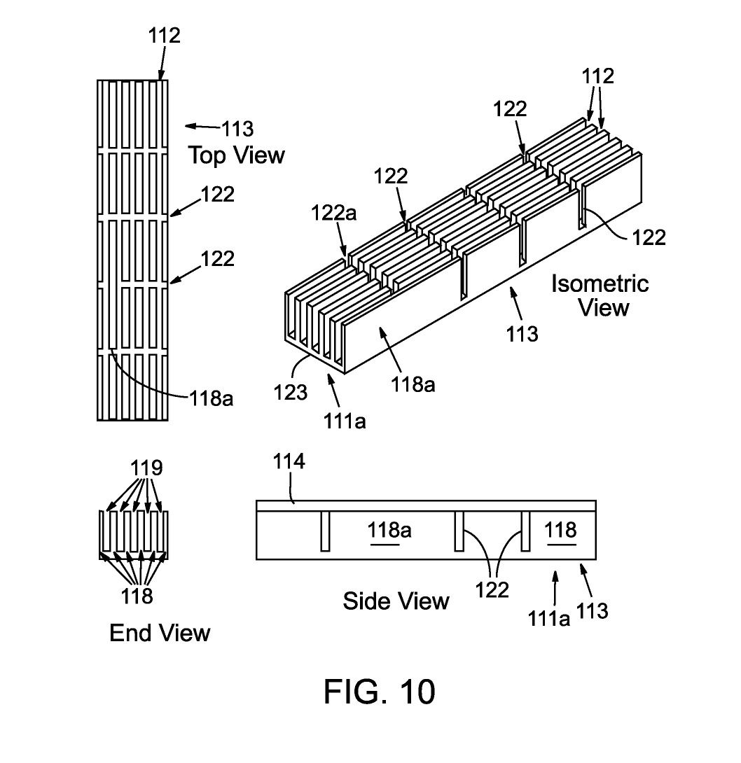

With reference to FIGS. 9, 9A and 10, a microchannel heat sink, such as the microchannel heat sinks 110, 120 (FIG. 2) can comprise a first substrate 113 comprising a unitary construction. The substrate can define the internal heat transfer surface 112 and the external heat transfer surface 111a. The first substrate 113 can comprise a material having a high thermal conductivity, such as an alloy of copper, or a silicon-based material. The internal heat transfer surface 112 can define internal flow channels 119 among plural fins 118.

Such microchannel substrates 113 can comprise materials having a relatively high conductivity. In addition to materials such as copper alloys and silicon, other materials such as diamond may be used.

A material having anistropic thermal conductivity can also be used. Such a material has a lower thermal conductivity in one direction, but higher thermal conductivity in another direction. For example, materials such as eGRAF® of GrafTech, International might be used. eGRAF™ has a thermal conductivity that is high in two dimensions (e.g., within a plane), and low in a third direction (e.g., perpendicular to the plane). eGRAF™ is typically utilized to spread heat across a plane of a heat shield while maintaining a low temperature perpendicular to the plane of the heat shield. A material such as eGRAF™ can be used for the heat sink For example, such a material can be used to provide a high thermal conductivity perpendicular to the base of the heat sink Stated differently, a heat sink could have a high thermal conductivity perpendicular to the base. In such an embodiment, the heat sink could have improved ability to transfer heat through surfaces in contact with the coolant. As a result, such a heat sink could be better able to transfer heat to the cooling fluid passing through the microchannels.

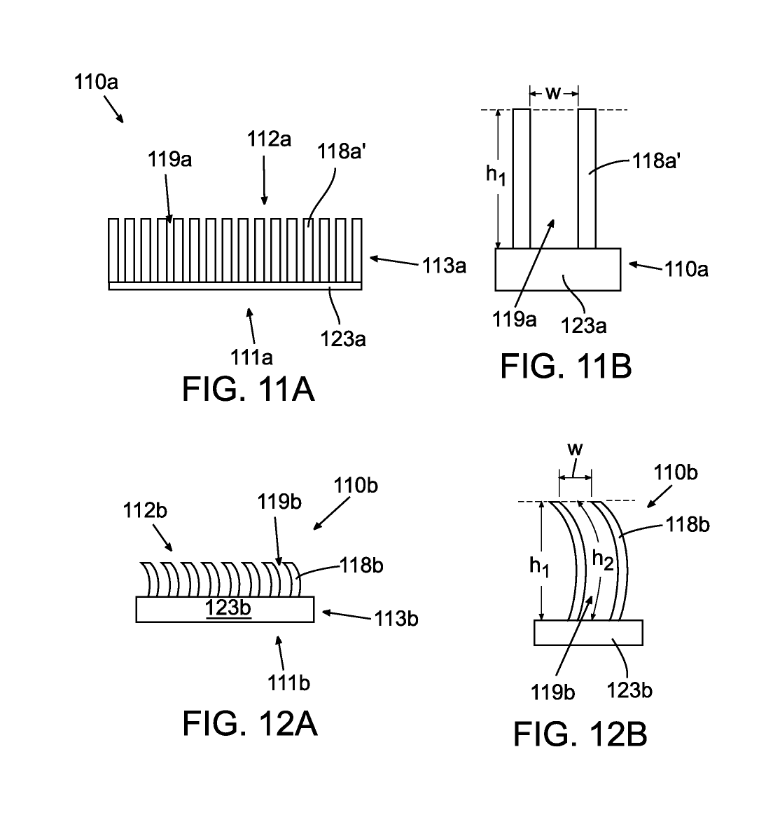

With further reference to FIGS. 9, 9A and 10, the internal heat-transfer surface 112 can define an array of outwardly extending features 118, 118a, such as fins (or channel walls) that define channels (e.g., flow microchannels 119 and cross-connect microchannels 122) therebetween. Stated differently, the internal heat transfer surface 112 can define an array of recessed regions (e.g., channels 119, 122) defining walls 118, 118a therebetween. In connection with microchannel heat sinks 110, 120, the fin and channel features of the internal heat transfer surface 112 have typical length scales on the order of about ten micrometers to about 1000 micrometers, and can be formed using various material removal techniques, such as chemical etching, micromachining, laser ablation and others, or material deposition techniques, such as a vapor-, or other, deposition technique. Other microchannel and/or fin forming techniques, such as skiving and/or microdeformation techniques described, for example, in U.S. Patent Application No. 61/308,936, filed Feb. 27, 2010, and assigned to the assignee of this application can be used. FIGS. 11 and 12, discussed more fully below, show schematic illustrations of fin and channel features formed using such skiving and microdeformation techniques.

Many configurations of internal flow channels are possible. For example, U.S. non-provisional patent application Ser. No. 12/511,945 entitled MICROSCALE COOLING APPARATUS AND METHOD, filed Jul. 29, 2009, discloses several configurations of internal flow channels compatible with single-phase and two-phase operation.

A cover plate (or lid) 114 (FIG. 10) can enclose an otherwise open top plane of the channels 119, 122, thereby defining an enclosed microchannel passageway through which a working fluid can pass.

### Lids

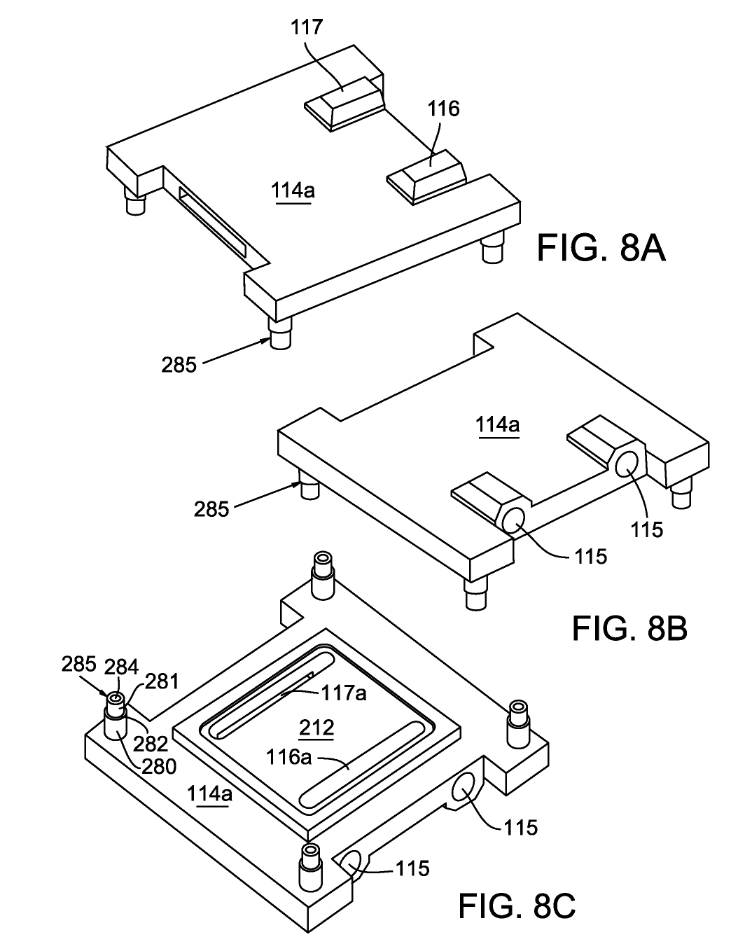

As shown in FIGS. 8A, 8B and 8C, and the side-view of FIG. 10, a second substrate can define a cover plate, or lid, 114, 114a (e.g., comprising a tin-plated aluminum alloy) configured to enclose a “top” of the channels 119, 122 defined by the internal heat transfer surface 112. As shown in FIGS. 8A, 8B and 8C, a lid 114a can define fluid couplings 115 configured to fluidicly couple an assembled microchannel heat sink to other portions of the cooling system. For example, the lid 114a can define an inlet coupler 116 and an outlet coupler 117 (FIG. 8A). A lid 114a and a microchannel heat sink substrate 113 (FIG. 9) can also define one or more internal plenums 123, 124 (FIG. 9) fluidicly adjacent one or both couplers 116, 117. Such plenums can be configured to distribute a working among a plurality of internal flow channels 119. For example, the lid 114a defines an inlet plenum 116a and an outlet plenum 117a. In passing through a microchannel heat sink that incorporates the lid 114a, the working fluid generally flows, in order, from an inlet coupler 116 to the inlet plenum 116a, through the flow microchannels 119, through the outlet plenum 117a, and to the outlet coupler 117.

### Overview of Microchannel Heat Sink Operation

As noted above, during operation, a microchannel heat sink 110, 120 can be thermally coupled to (e.g., positioned adjacent or alternatively, adjoining) a heat-dissipating device, such as an electronic component 42, 44 (FIG. 2). Heat Q₁, Q₂ (FIG. 2) dissipated by the heat-dissipating device can transfer through an external heat transfer surface 111, 121 (FIG. 2) of the heat sink 110, 120, through the internal heat transfer surface 112 and into a working fluid (e.g., a coolant) flowing through the microchannel heat sink

The working fluid (e.g., HFE 7000) can absorb heat from the internal heat transfer surface 112 through convective (e.g., advective and conductive) heat transfer mode as the fluid passes through the flow channels 119 and past the fins 118. Examples of working fluids are water, dielectric fluorochemical coolants, Novec™, R134a, R22, and/or other refrigerants, including high pressure refrigerants, might be used. The fluid can be selected, at least in part, based on the particular pump (not shown) selected for use. In addition, a working fluid can be selected based in part on the fluid's material properties, such as, for example, a latent heat of phase change, as well as how the fluid's phase transition temperature varies with pressure. For example, as a working fluid vaporizes, an internal pressure within a closed cooling system can increase. Accordingly, phase transition temperature variation with pressure can be a factor in selecting a working fluid. In some instances, a fluid having a phase transition temperature of less than about eighty-five degrees Celsius over a wide range of pressures can be used. For example, such a fluid can have a phase transition temperature of greater than about 40° C. and less than about 45° C. over a wide range of pressures (e.g., about 1 atmosphere, plus or minus 20%). Such a fluid can be more likely to boil when cooling an electronic device at a temperature less than the device's upper threshold temperature. Thus, the specific coolant used in connection with a given cooling system can vary.

HFE 7000 boils at about 35° C. (at 1 atm (atmospheres) absolute pressure), and between about 50° C. and about 60° C. (between about 1.2 atm and about 1.6 atm absolute pressure). HFE 7000 has a latent heat of vaporization measuring about 142 kJ/kgK. Other working fluids can be used in combination with disclosed microchannel heat sinks, such as, for example, water. A working fluid, as it passes from a microchannel heat exchanger 110, 120, carries with it heat absorbed from the internal heat transfer surface 112 as described above. Heat absorbed by the working fluid in the microchannel heat exchanger 110, 120 can be rejected from the fluid in another portion of the cooling system (e.g., from a condenser 130, (FIG. 2)) and thus provide on-going, continuous cooling of the device 42, 44.

Significant amounts of heat can be absorbed by many working fluids that remain in a liquid phase as heat Q₁, Q₂ is absorbed. Nonetheless, many fluids have a latent heat of vaporization (i.e., the amount of energy required to cause a unit mass of the fluid to change from the liquid state to a gaseous (vapor) phase at a specified pressure), or condensation (i.e., the amount of energy required to cause a unit mass of the fluid to change from the gaseous (vapor) phase to a liquid phase at a specified pressure) collectively referred to here as a “latent heat or phase change” that exceeds the fluid's specific heat (i.e., the amount of energy required to change a unit mass of the fluid at a specific temperature and pressure by a unit of temperature). Since many fluids change from a liquid to a vapor phase at a substantially constant temperature, a fluid having a high latent heat or phase change can absorb energy at a correspondingly high rate while remaining at a substantially constant temperature. As a vaporized fluid condenses, the energy content of the fluid drops in accordance with the fluid's latent heat of condensation. Accordingly, the heat absorbed during vaporization can be rejected by condensing the fluid.

Microchannel heat sinks in which at least some of the working fluid vaporizes during normal operation are referred to herein as “two-phase” microchannel heat sinks. Heat sinks in which no (or insignificant amounts) of the working fluid vaporizes during normal operation are referred to herein as “single-phase” heat sinks.

As noted above, microchannel heat sinks 110, 120 can operate in a two-phase “mode”. Although referred to as a “two phase” heat sink, the microchannel heat sinks 110, 120 can operate in a single-phase or a two-phase mode. For example, a coolant might remain in its liquid phase under relatively high coolant flow rates and/or when exposed to relatively low dissipative heat fluxes. In such situations, the microchannel heat sink 110, 120 operates as a single-phase heat sink If the coolant flow rate is sufficiently low and/or the heat flux to be dissipated is sufficiently large, the liquid coolant can reach its boiling point while still flowing through the heat sink 110, 120, and flow boiling occurs. This results in the heat sink 110, 120 operating as a two-phase heat sink During operation in such a two-phase mode, the latent heat exchange associated with transition of the coolant from liquid to vapor may more efficiently remove heat from the two-phase microchannel heat sink.

A two-phase microchannel heat sink can be used to achieve a variety of benefits. Effective cooling can be achieved since the latent heat of the liquid-to-vapor phase transition allows the vaporizing fluid to absorb large quantities of heat with low temperature gradients within the fluid.

### Fin Configurations

The flow microchannels 119 can be a series of parallel, symmetric, rectangular cross-section micro-slots, or depression, formed in a base. The flow microchannels 119 have a width and are defined by opposing channel walls 118, 118a, which also have a width and height. The flow microchannels 119 may be no larger than in the microscale regime. For example, flow microchannels may range from ten to one thousand microns in width for certain embodiments. Smaller widths may also be possible. The channel walls 118 may have a thickness in the one-hundred micron range, a height in the hundreds of microns range. However, other channel cross-sections, widths, heights, channel directions are possible for the flow microchannels 119.

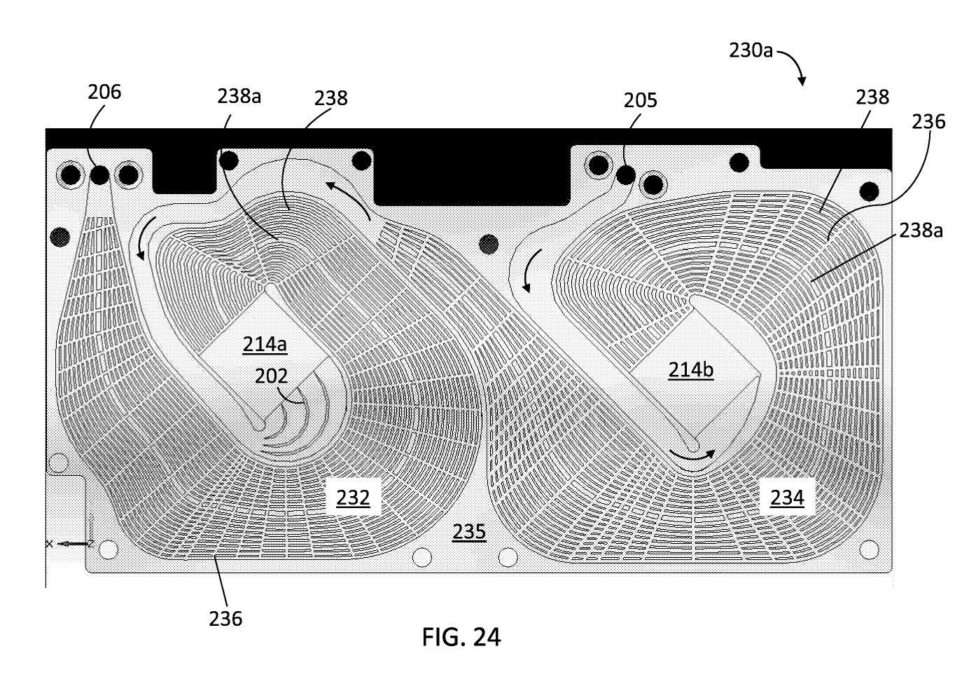

Although the microchannels 119 shown in FIGS. 9, 9A and 10 are substantially parallel and symmetric (e.g., having rectangular cross-sections), some microchannels are not parallel, linear, symmetric, and/or rectangular. For example, a flow microchannel 122 can have one or more cross-sectional dimensions that change along a streamwise length of the flow microchannel. Also, one flow microchannel can be dimensioned differently than another flow microchannel in the same substrate, heat sink, or cooling system. In still other embodiments, flow microchannels can be curved and/or are not perpendicular to the inlet or the outlet. For example, although FIG. 24 illustrates condenser fin channels, a flow microchannel 119 can curve through one or more bends and/or can taper along a streamwise flow direction.

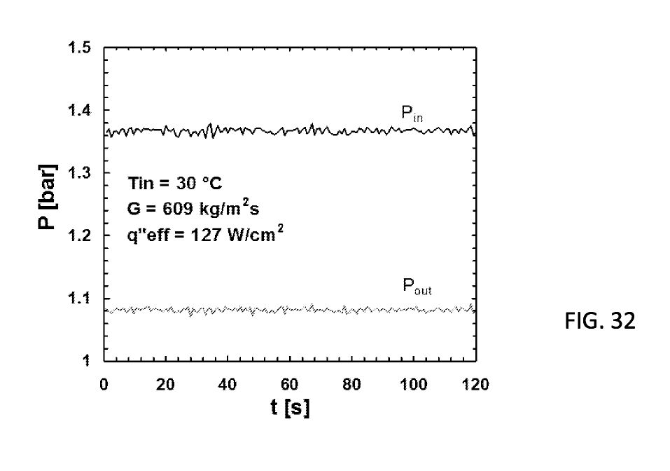

In addition to flow microchannels 119, the internal heat transfer surface 112 can define one or more cross-connect channels 122 (FIGS. 9, 9A and 10). Cross-connect channels 122 can at least partially equilibrate a pressure field within the working fluid as the working fluid boils (e.g., changes phase from liquid to gas) within the flow microchannels 119. The cross-connect channels 122 allow vapor and/or liquid to flow between adjacent flow microchannels 119 (e.g., transversely to a general streamwise flow direction). Such localized transverse flows can substantially equalize a coolant pressure among the flow microchannels 119. As a result, the working fluid can enter the flow microchannels 119 from an inlet 123 in a substantially uniform manner, rather than entering the flow microchannels in a non-uniform manner, as can occur in the absence of cross-connect channels 114. Stated different, in the absence of cross-connect channels 122, a working fluid would tend to enter a low-pressure gradient flow microchannel (such as those microchannels where the working fluid is not boiling) preferentially over an adjacent flow microchannel having a higher pressure gradient along its length (such as boiling can induce). Such a non-uniform flow field passing through hydraulically parallel flow microchannels can lead to flow microchannel dry-out and/or unstable flow oscillations among the various flow microchannels, and thereby reduce the cooling effectiveness of the microchannel heat sink Providing cross-connect microchannels or other pressure-equilibrating features can mitigate (or eliminate) dry-out and unstable flow oscillations (and their deleterious effects on performance). Such stable performance is indicated by the graph shown in FIG. 32, and is discussed more fully below.

Cross-connect channels 122 can have characteristic dimensions on the order of about 10 microns to about 1000 microns. Smaller characteristic lengths are also possible. Departures from the illustrated cross-connect channel geometries are also possible. For example, such cross-connect channels can have a varying cross-sectional area, and can be curved. Cross-connect channels 122 can be partially enclosed by a lid 114, as shown in the isometric view in FIG. 10.

As shown in FIGS. 9, 9A and 10, cross-connect channels 122 can be oriented transversely substantially perpendicularly to a general flow direction 241 (FIG. 9A) of the working fluid (e.g., working fluid generally follows a streamwise flow path defined by the flow microchannels 119 and indicated by the arrow 241). Some cross-connect channels 122, such as the channel 122a, extend partially across the width W1 (FIGS. 9 and 10) of the internal heat transfer surface 112 and/or intersect fewer than all of the flow microchannels 119. Other cross-connect channels 122 extend across the width W1 and/or intersect all of the flow microchannels 119. In some microchannel heat sinks 110, 120 all of the cross-connect channels 122 extend across the width W1, and in other instances, none of the cross-connect channels extend across the width W1. The cross-connect channels 122, 122A can be uniformly spaced apart along a streamwise flow direction 241 (FIG. 9A) defined by the flow microchannels 119 (e.g., at about one-millimeter intervals), or can be spaced apart non-uniformly along the streamwise flow direction (e.g., substantially randomly).

The inlet 123 and outlet 124 correspond to respective plenums 116a, 117a at respective inlet and outlet ends of the two-phase microchannel heat sink heat transfer surface 212 and adjacent the inlet and outlet couplers 116, 117 (FIG. 8C). The inlet 123 and outlet 124 are configured, respectively, to introduce coolant to and discharge coolant from the flow microchannels 119, respectively. Thus, coolant flows along the flow microchannels 119 from the inlet 123 to the outlet 124. Stated differently, the flow microchannels 119 are configured to carry the coolant, which can exist in one or two-phases, between the inlet 123 and outlet 124.

The two-phase microchannel heat sink 110, 120 can also define cross-connect channels 122, 122a. In some instances, the cross-connect channels 122 may be no larger than in the microscale regime. For example, in some embodiments, the cross-connect channels 122 may have a width in the range of ten to one thousand microns. Smaller widths may also be possible. Although shown as having the same width and being of rectangular cross-section, other channel cross-sections, widths, heights, and channel directions are possible for the cross-connect microchannels 122. In some embodiments, the cross-connect channels may not be parallel, linear, symmetric, and/or rectangular. Similarly, some embodiments, the cross-connect channels 122 may have varying widths. For example, a particular cross-connect channel may have a width that changes along the length of the cross-connect channel. In addition, one cross-connect channel 122 may not have the same width as another cross-connect channel. The cross-connect channels 122 may be closed using the cover plate 114, or lid 114a.

The coolant flows generally from the inlet 123 to the outlet 124 in a streamwise flow direction 241 (FIG. 9A). As noted above, the cross-connect channels 122 may be used to at least partially equilibrate a pressure field for boiling of the coolant across the portion of the plurality of flow microchannels. The cross-connect channels 122 allow for vapor and/or liquid communication between flow microchannels 122. When a two-phase microchannel heat sink 110, 120 operates in a two-phase mode, the pressure of the boiling coolant can equilibrate along the length of each cross-connect channel 122. Stated differently, the pressure may be substantially uniform along each cross-connect channel 122. As a result, the pressure of the coolant flowing through the flow microchannels 119 is equilibrated across at least a portion of the width, W1, of the two-phase microchannel heat sink (FIG. 9). For a cross-connect channel, such as the channel 122a, the pressure of the boiling coolant is equilibrated across only a part of the width of the two-phase microchannel heat sink Thus, a cross-connect channel 122a on one side of a channel wall 118a may have a different pressure than a cross-connect channel 122 on an opposing side of the channel wall 118a.

As discussed above, the cross-connect channels 122 can be spaced at various intervals and can be so configured as to equilibrate pressure along their respective lengths. The location, length, and other features of the cross-connect channels 122 might vary based upon the implementation. In some embodiments, cross-connect channels 122 may be spaced at larger intervals as long as the cross-connect channels 122 are sufficiently close that unstable pressure oscillations are reduced or eliminated in the operating range of the heat sink In other embodiments, the cross-connect channels 122 may be more closely spaced. However, in such embodiments, it is desirable to locate the cross-connect channels 122 sufficiently far apart that a satisfactory flow of coolant through the flow microchannels 119 can be maintained.

### High Aspect Ratio Features

As used herein, “aspect ratio” means a ratio of a first dimension to a second dimension. For example, a flow channel (or channel) can define a rectangular cross-section having a height and a width. Accordingly, an aspect ratio of the flow channel can be a ratio of the microchannel's height to the microchannel's width.

As used herein, “high aspect ratio” means an aspect ratio measuring at least 10:1.

As used herein, “high aspect ratio microchannel” means a microchannel defining a flow cross-section having a measure of height and a measure of width, wherein a ratio of the measure of height to the measure of width is at least 10:1. For example, a microchannel having a rectangular flow cross-section measuring 0.1 mm wide and 1.0 mm tall has an aspect ratio of 10:1, and therefore is considered a high aspect ratio microchannel.

The fins 118 of some microchannel heat sinks define high-aspect-ratio microchannels. As with microchannels of heat sinks described above, each high aspect ratio microchannel can be bounded on opposing sides of its flow periphery by adjacent fins 118, on a bottom side by a base 123 (e.g., a portion of the substrate 113) and a lid 114.

Referring to FIGS. 11A, 11B, 12A and 12B, schematic illustrations of working microchannel heat sinks 110a, 110b comprising high aspect ratio microchannels are shown. As with microchannels 119 described above, each microchannel 119a, 119b can extend longitudinally of the respective heat sink 110a, 110b between an inlet end and an outlet end in a general streamwise flow direction defined by the high aspect ratio microchannels. At least some of the fins 118a′, 118b define a corresponding cross-connection opening (not shown) extending therebetween. The cross-connection opening can be configured, as described above, to fluidicly couple adjacent flow microchannels 119a, 119b to one another. Such cross-connection openings or cross-connection channels, can extend transversely relative to the streamwise flow direction defined by the microchannels.

In some instances, a cross-connection opening e.g., a cross-connection channel, can have a longitudinal dimension (e.g., in a streamwise flow direction) measuring between about 1 to about 3 times a width w (FIGS. 11 and 12) of a high aspect ratio microchannel 119a, 119b. The cross-connection opening (not shown) can extend downwardly from a distal end of the fin toward the base 123a, 123b. Some cross-connection openings extend downwardly through the entire fin 118a, 118b to the respective base 123a, 123b, and some cross-connection openings extend downwardly through less than the entire fin, such as, for example, through about 25%, about 50% or about 75% of the fin. Some cross-connection openings define an aperture through the fin, such that the distal end of the fin defines a continuous edge, and the cross-connection opening extends through a portion of the fin 118a, 118b between the base 123a, 123b and the distal end of the fin.

As with other microchannel heat sinks disclosed herein, the base 123a, 123b of a high aspect ratio microchannel heat sink can define a substantially flat surface 111a, 111b configured to thermally couple to a corresponding substantially flat surface defined by a packaged electronic component, such as a packaged semiconductor die. The fins 118a, 118b and base 123a, 123b can form a unitary construction and can be formed from a unitary substrate 113a, 113b, as described more fully below with regard to working samples of such high aspect ratio microchannel heat sinks.

### Working Samples—High Aspect Ratio Microchannel Heat Sinks

In some working embodiments of two-phase microchannel heat sinks, the flow microchannels 119, 119a, 119b (FIGS. 8, 9, 11 and 12) define a series of substantially parallel, symmetric, rectangular cross-section micro-slots, or recessed channels, formed in a substrate 113. The flow microchannels 119, 119a, 119b can have a width W and respective heights h₁, h₂ (FIGS. 11 and 12) and are defined by respective channel walls (or fins) 118, 118a, 118b, which define a corresponding height and fin thickness. The channel walls 118, 118a, 118b can have a fin thickness on the order of about one-hundred micron and a height on the order of several-hundred microns.

FIG. 11 and FIG. 12 show schematic illustrations of respective working samples of high aspect ratio microchannel heat sinks 110a, 110b having several spaced cross-connections 122 fluidicly coupling adjacent microchannels 118a, 118b, as described above. In each of the working samples, each fin 118a, 118b measures about 100 microns (or about 0.1 mm) thick and about 1.2 mm tall (i.e., each fin has about a 12:1 aspect ratio). Each microchannel 119a, 119b between the respective fins 118a, 118b has a width w measuring about 0.1 mm and a height h₁ measuring about 1.2 mm, thus defining a high aspect ratio microchannel having about a 12:1 aspect ratio. The fins 118a were formed using a microdeformation process. The fins 118b were formed using a skiving process.

Several cross-connections 122 extend between adjacent microchannels 119a, 119b, thereby fluidicly coupling the adjacent microchannels to each other. The cross-connections 122 of the working samples were cross-cut into pre-existing fins (e.g., fins formed from a skiving technique). Stated differently, after the fins 118a, 118b were formed, a micromachining process was performed to mill cross-connection openings (not shown, but similar to the channels 122) extending through the fins 118a, 118b. Nonetheless, as disclosed in U.S. Patent Application No. 61/308,936, filed Feb. 27, 2010, and assigned to the assignee of this application, the fins 118b can be formed using a skiving process to form the fins 118b and the corresponding cross-connections simultaneously.

Referring to FIG. 12A, each fin 118b is about 100 microns (or about 0.1 mm) thick and about 1.2 mm tall (i.e., extends from the base 123b by a distance h₁, measuring about 1.2 mm. Each microchannel 119b has a width w measuring about 0.1 mm and a height h₁ measuring about 1.2 mm, defining a high aspect ratio microchannel having about a 12:1 aspect ratio. The fins 118b are shown having a slight curvature resulting from the skiving process, forming microchannels 119b with a corresponding slightly-curved cross-section. The arclength h₂ is about the same as the height h₁ for the slight curvature of the working sample. In some instances, the cross-section of the microchannels 119b can have more curvature, and the arc length h₂ can be substantially greater than the height h₁. In these instances, microchannel aspect ratio can be defined based on the arc length h₂.

### Mounting Features

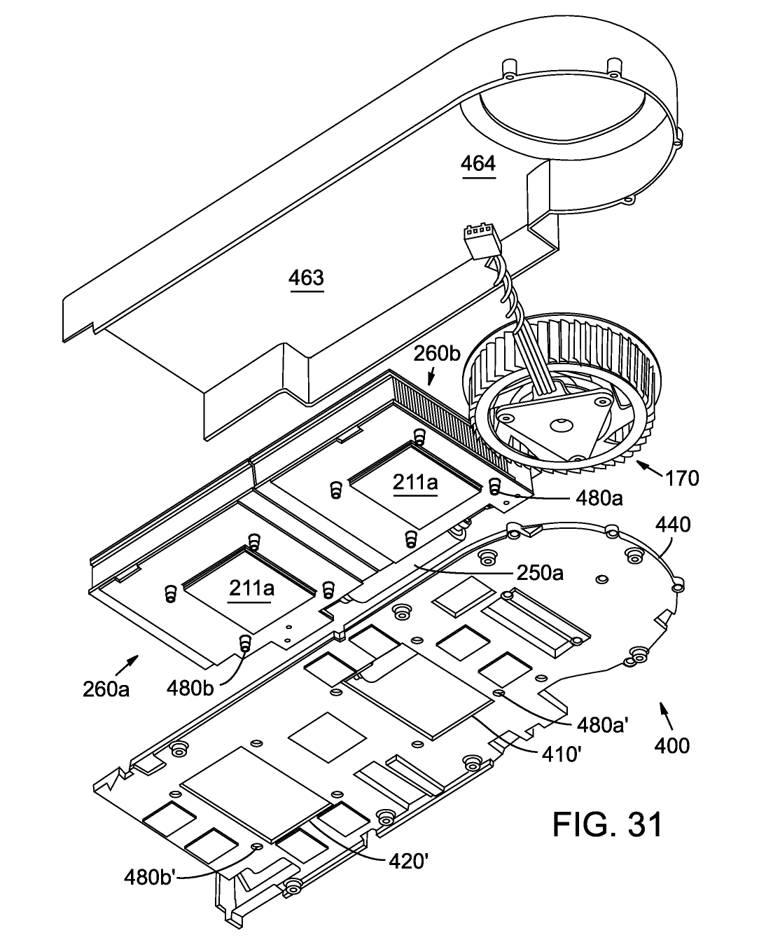

As shown in FIGS. 8A, 8B and 8C, a portion of a microchannel heat sink, such as the lid 114a, can define one or more legs 280 (480a, 480b in FIG. 31) configured to secure the microchannel heat sink to a cooling system chassis 60 (FIG. 4A), 440 (FIG. 31) and/or to operatively position the microchannel heat sinks 110, 120 relative to a substrate 46 (FIG. 4A) and electronic components 42, 44 mounted thereto. With reference to FIG. 8C, the legs 280 can comprise a narrow portion 281 configured to extend through the chassis 240 and/or substrate 46. The legs 280 can also define one or more shoulders 282 configured to engage or rest against the chassis 240 and/or substrate 46, respectively, thereby limiting the extent to which the narrow portion 281 of the legs 280 extend therethrough. The distal end 283 of each leg 280 (relative to the body of the microchannel heat sink) can define an opening 284 and a corresponding recessed opening 285 extending lengthwise (e.g., a portion of the length of the leg) of the leg. The recessed opening 285 can matingly receive a stud, a screw or other fastening device having a head such as a headed stud extending through a retainer clip 71, 72 (FIG. 4A). Such a fastener 71a-d, 72a-d can retain the leg 280 relative to the chassis 60 and/or the substrate 46 through which the leg extends. In some embodiments, the recessed opening 285 can be threaded so as to threadingly engage corresponding threads of a screw body.

### Summary of Microchannel Heat Sinks

Furthermore, the combination of the flow microchannels 119 (FIG. 9) and cross-connect channels 122 allow for reduced pressure oscillations and stable flow of the boiling liquid coolant. These attributes may enable the two-phase microchannel heat sink 110 to stably and repeatably dissipate high heat fluxes, as indicated in FIG. 3, particularly from small areas. Two-phase microchannel heat sinks 110, 120 can also have low thermal resistance to heat dissipation, large surface-area-to-volume ratio, small heat sink weight and volume, small liquid coolant inventory, and a smaller flow rate requirement. A more uniform temperature variation in the flow direction and higher convective heat transfer coefficients may also be achieved. Consequently the two-phase microchannel heat sink may be suitable for thermal management of high-power-density electronic devices including but not limited to devices such as high-performance microprocessors, laser diode arrays, high-power components in radar systems, switching components in power electronics, x-ray monochromator crystals, avionics power modules, and spacecraft power components.

### Condenser

As noted above with regard to FIG. 2, a cooling system 100 can comprise a condenser 130 configured to reject heat Qₒᵤₜ from the working fluid in the cooling system to a fluid in the environment. In some instances, the condenser can reject the heat Qₒᵤₜ to air from the environment. In other instances, the condenser can reject the heat Qₒᵤₜ to another cooling system, such as, for example, a vapor-compression refrigeration cycle, a single-phase cooling cycle (e.g., a water chiller can supply chilled water to a cold-plate thermally coupled to the condenser), or even a second two-phase cooling cycle having an evaporator thermally coupled to the the condenser.

As described more fully below, such condensers 130 can receive heated working fluid (e.g., in a sub-cooled liquid phase, in a saturated liquid and vapor phase, or in a vapor phase) from one or more microchannel heat sinks 110, 120, or another component (e.g., a manifold) fluidicly coupled between a microchannel heat sink and the condenser.

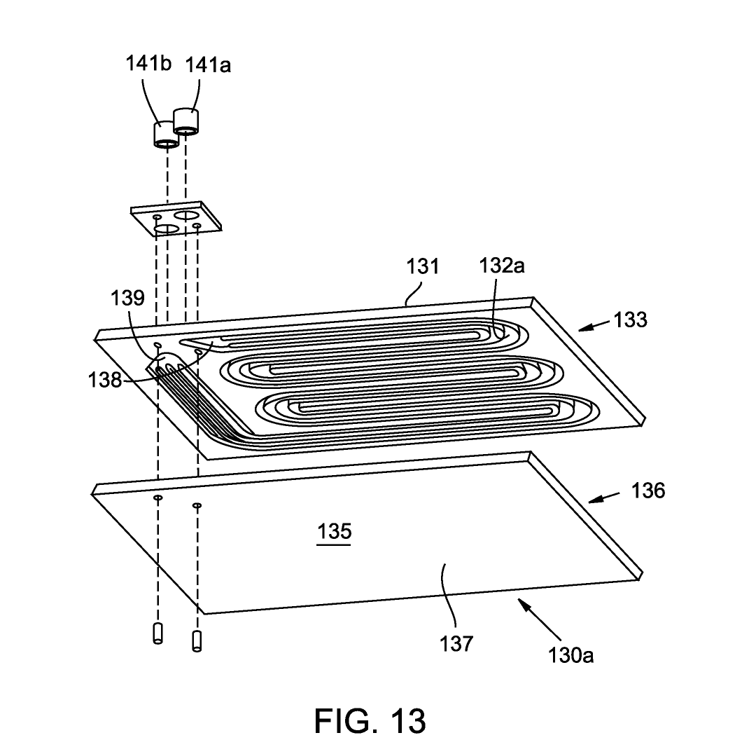

As shown in FIG. 13, by way of example, a condenser 130a can comprise a laminate construction. For example, a first substrate 131 can define an internal heat transfer surface 132a through which heat passes from the working fluid (not shown) and an external heat transfer surface 133 through which heat Qₒᵤₜ can pass to the environment (e.g., an environmental fluid or another body, such as, for example, a heat exchanger with an air cooled heat sink 162 being but one example). The internal surface 132a can define one or more recessed regions defining one or more flow channels through which the working fluid can pass to reject heat (e.g., convectively) through the internal heat transfer surface 132a. The internal surface 132a can define a plurality of fins, as with the condenser plate 230a shown in FIG. 24.

A second substrate, or lid, 135 can matingly engage the first substrate 131 so as to enclose the recessed regions 132a and define enclosed condenser flow channels. The lid 135 can also define an internal heat transfer surface 136 through which can heat pass from the working fluid to an external heat transfer surface 137. Heat can pass to the environment (e.g., to a heat sink or other cooling system) through the surface 137 in some instances. As with the surface 133, the external heat transfer surface 137 of the lid 135 can be directly exposed to an environmental fluid, such as air 101, or can be thermally coupled to a heat exchanger, such as an air-cooled heat sink 162 (as shown, for example, in FIG. 15). The lid 135 can comprise a heat sink base, and fins or other extended surfaces (not shown) can extend therefrom for facilitating heat exchange with the environmental fluid 101 (as described more fully below with regard to FIG. 16). For example, the environmental fluid can pass among such extended surfaces and absorb heat rejected by the working fluid.

Internally, the condenser 130a can define an inlet plenum 138 and/or an outlet plenum 139 fluidicly coupling the flow channel(s) with one or more inlet 141a and/or outlet 141b couplers, respectively. Such plenums 138, 139 can distribute working fluid among, or collect working fluid from, plural flow channels, providing a flow transition between the flow channels and the inlet and/or the outlet couplers 141a, 141b.

A condenser can define a single continuous flow channel, such as a circuitous channel fluidicly coupled to a plurality of microchannel heat sinks. Alternatively, as indicated in FIG. 2, a condenser can define a plurality of flow channel regions 132, 134 corresponding to each respective microchannel heat sink 110, 120. For example, with reference to FIG. 2, a condenser 130 can define a first flow channel region 132 corresponding to the first microchannel heat sink 110 and a second flow channel region 134 corresponding to the second microchannel heat sink 120. In such an embodiment, a primary heat transfer path for each flow channel region can be from the working fluid in each region 132, 134 to the environment, although a nominal net heat exchange between the flow regions can occur, as by conduction through the condenser plate(s).

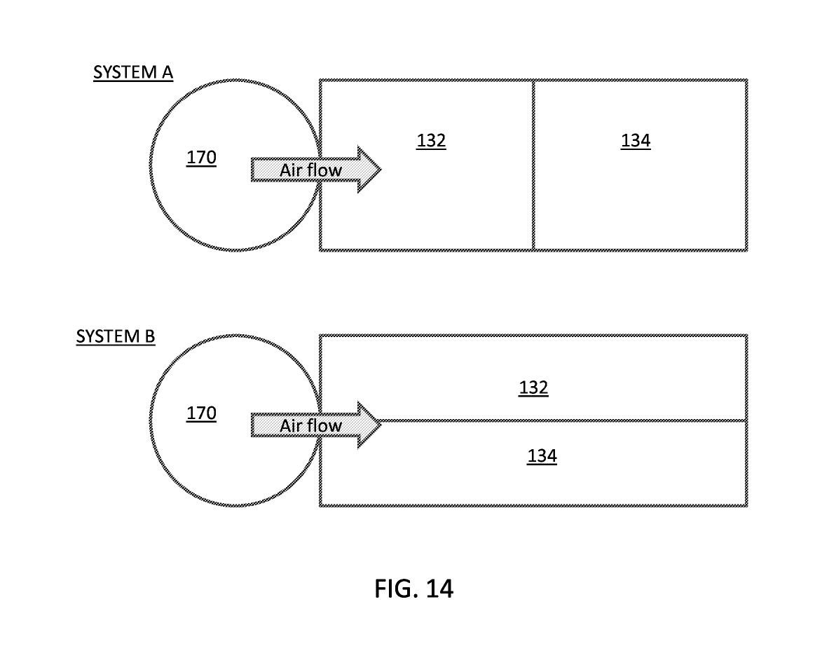

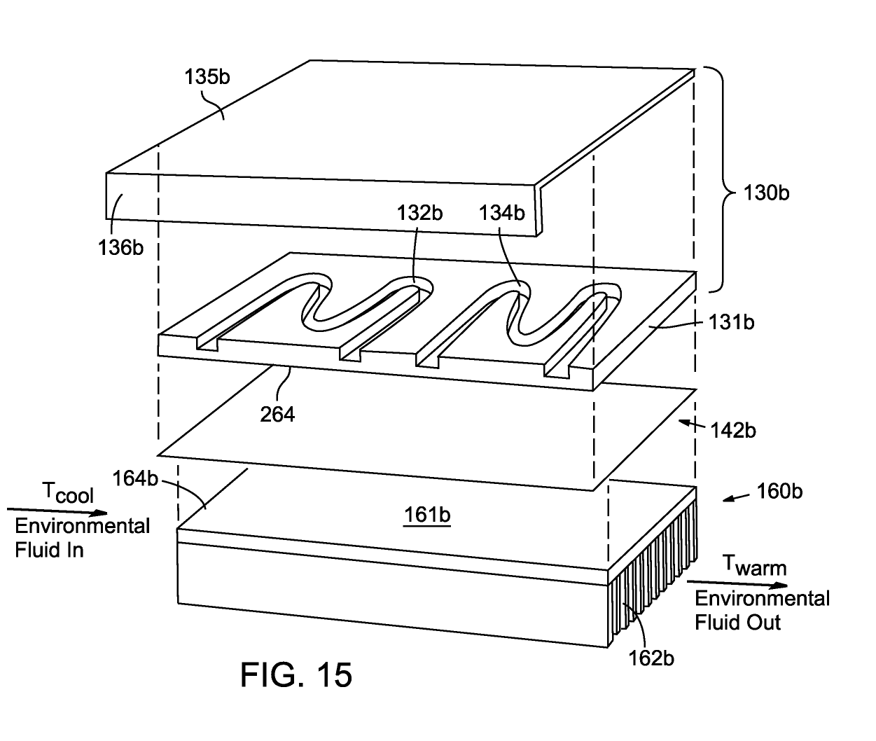

FIG. 14 schematically shows two alternative configurations for relative placement of the first flow channel region (or condenser portion) 132 and the second flow channel region 134. In the “System A” configuration, the flow channel regions 132, 134 are cooled in series (as with the configuration shown in FIGS. 15 and 16). In other words, an environmental fluid 101 (labeled “Air Flow” in FIG. 14A) can pass through a portion of the heat exchanger adjacent the first flow channel region 132 before passing through a portion of the heat exchanger 162 adjacent the second flow channel region 134. Consequently, in the System A configuration of FIG. 14A, the second flow channel region 134 is exposed to an environmental fluid (e.g., air) heated by the first flow channel region 132. In some instances, such serial cooling of the condenser portions 132, 134 provides insufficient cooling for the downstream (e.g., the second) flow channel region 134.

In the “System B” configuration shown in FIG. 14A, the flow channel regions 132, 134 are cooled in parallel. In other words, the first flow channel region 132 is adjacent a first portion of a heat exchanger, or cooler, and the second flow channel region 134 is adjacent a second portion of the heat exchanger. The first and second portions of the cooler can be fluidicly coupled in parallel with each other. With such a configuration, a first flow of environmental fluid passes adjacent the first portion of the cooler and a second flow of environmental fluid passes adjacent the second portion of the cooler. The first flow and the second flow can remain substantially isolated from each other as they pass through the respective heat exchanger portions. In such a configuration, neither flow channel region 132, 134 is substantially exposed to an environmental flow field that has been pre-heated by the other flow channel region since the first flow of environmental fluid and the second flow of environmental fluid remain substantially separate. Such parallel cooling can balance cooling performance between (e.g., provide similar rates of heat transfer from) the first flow channel region 132 and the second flow channel region 134 using a single heat exchanger (or cooler).

In the System A and the System B configurations, the condenser 130 and heat sink 162 (FIG. 2) assembly can comprise a counter-flow heat exchanger. In other words, a general flow direction of the environmental fluid can be opposite a general flow direction of working fluid passing through the condenser 130 (e.g., through the flow channel regions 132, 134). Such a counterflow heat exchanger can substantially improve heat transfer rates between the working fluid and the environmental fluid 101 (air, in this instance). Stated differently, to provide high overall rates of heat transfer from the working fluid to the environmental fluid, the general flow direction of the working fluid through each of the flow channel regions 132 and 134 can be in a direction opposite the direction of flow of the Air Flow (e.g., working fluid can flow from right to left and the airflow can flow from left to right, as indicated by the arrows in the System A and System B configurations shown in FIG. 14).

With reference to FIGS. 15 and 16, alternative condenser and cooler (heat exchanger) configurations are shown. Referring to FIG. 15, a condenser plate 130b can be a separate component brought into thermal contact with the cooler 160b (e.g., an air-cooled heat sink 162b). For example, as shown in FIG. 15, the base member 161b of a heat sink 162b and a first condenser substrate 131b (similar to the laminated substrate 131 shown in FIG. 13) can be thermally coupled to each other (e.g., brought into an adjoining relationship with a film of thermal interface material (e.g., thermal grease, solder, etc.) 142b disposed therebetween). The base member 161b of the air-cooled heat sink 162b can comprise a first surface 164b for matingly engaging a corresponding opposed surface 264 of the condenser plate 130b, e.g., each surface 164b, 264 can be substantially flat. A thermal interface material 142b (e.g., a thermally conductive grease or paste, solder or a composite material, such as a conventional grease or paste having a suspension of thermally conductive particles, or “fill material”) can be applied to the interface between the mating surfaces 164b, 264 to improve the thermal coupling between the surfaces. Referring still to FIG. 15, the first and second flow channel regions 132b, 134b each correspond to a respective microchannel heat sink, and can be fluidicly coupled thereto, for example, in a manner as described above with reference to FIG. 2. A lid 135b can enclose an otherwise open top portion of the flow regions 132b, 134b.

As shown in FIG. 16, a condenser 130c can be integrated with a cooler 160c. For example, a base 131 c of a heat sink can define separate flow regions 132c, 134c, similar to the flow regions 132b, 134b described above with reference to FIG. 15. The recessed flow channels 132c, 134c in the unitary construction 131 c can fluidicly couple to respective microchannel heat sinks 110, 120 (FIG. 2). The alternative condenser construction 130c shown in FIG. 16 eliminates one of a separate condenser substrate 131b and a heat sink base 164b (FIG. 15), and further reduces the overall thickness between the condenser channels 132c, 134c and the fins 162c of the cooler subassembly. Such a thin design allows the fins 162c to increase in length compared to the fins 162b shown in FIG. 15 for a fixed overall height of the condenser and fin assembly 130b, 162b and 130c, 162c. In some instances, the fins 162c can increase in length compared to the fins 162b by as much as the sum of the thicknesses of the base 161b and the thermal interface material 142b. Such a unitary construction 131c can thus allow the air-side thermal resistance to decrease, thereby significantly improving the overall cooling performance of the cooling system.

Some lids 135b, 135c (FIGS. 15, 16) can comprise one or more walls 136b, 136c extending substantially perpendicularly to and positioned outboard of the first substrate 131b, 131c of the condenser 130b, 130c. For example, one or more such walls 136b, 136c can partially define an environmental fluid conduit, or shroud, 163 (FIG. 4B) configured to direct the environmental fluid as it passes among the extended surfaces 162b, 162c of the cooler 160b, 160c (e.g., to reduce or eliminate a flow bypass that otherwise might occur, as described above with reference to FIG. 4B). Some lids 135b, 135c comprise a thermally conductive material (e.g., an alloy of aluminum or copper). Such lids can be exposed to the environmental fluid and provide an additional heat transfer path for rejecting heat (e.g., heat Q_{2,out} (FIG. 2)) from the condenser 170b, 138c to the environmental fluid.

### Cooling Systems

Examples of compact microscale heat transfer systems comprising features as described above will now be described. In particular, each of the following three system integration examples can be configured to fit within the physical volume defined by the PCIe Specification.

### System Integration

### Example 1

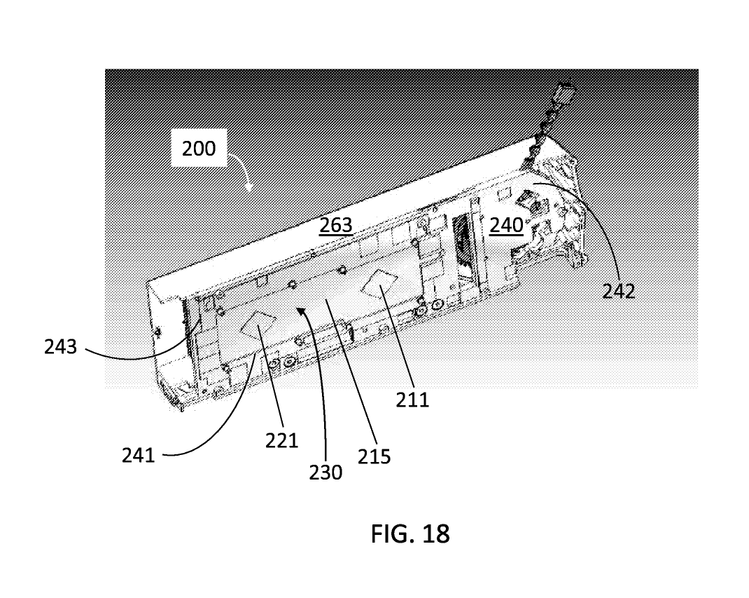

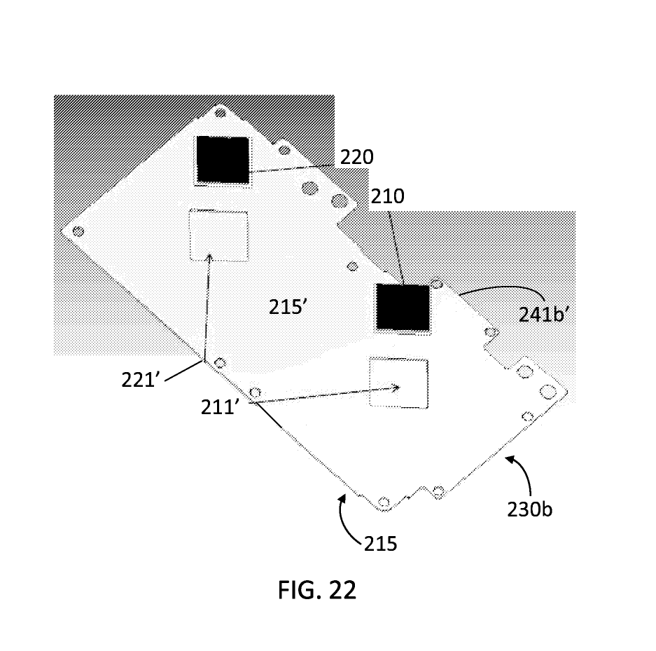

Referring now to the drawings shown in FIG. 17 through FIG. 24, a first compact, microscale heat transfer system, or cooling system, 200 will now be described. As with the cooling system 100 shown schematically in FIG. 2, the cooling system 200 comprises first and second microchannel heat sinks 210, 220 (FIG. 22) fluidicly coupled to respective condenser portions 232, 234 (FIGS. 18, 20-24). A pump similar to the pump 150′ shown in FIG. 7 and the pump 250a shown in FIG. 5 and being so configured as to be housed within the two-piece pump-housing manifold 255a and 255b (FIGS. 7A and 7B) adds sufficient pressure head to a working fluid as to circulate the working fluid among the heat sinks 210, 220 and the respective condenser portions 232, 234.

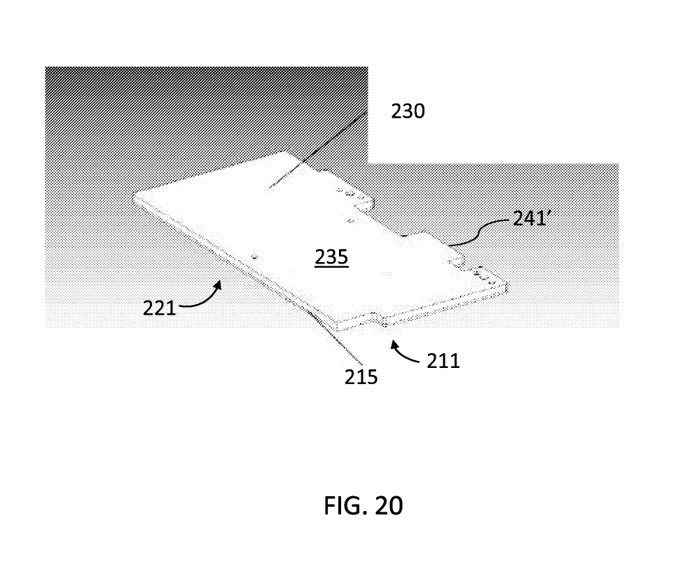

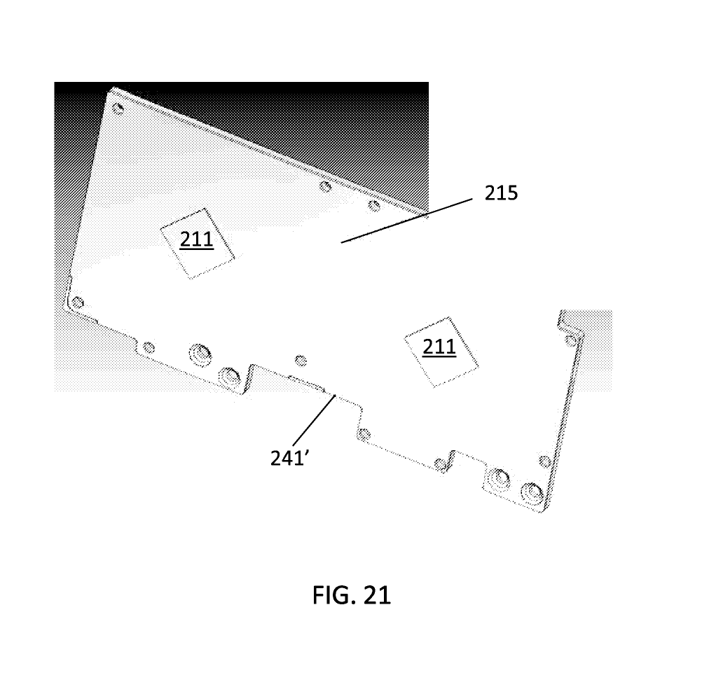

As described more fully below, the heat sinks 210, 220 and condenser portions 232, 234 are integrated into a laminated subassembly 230 (FIG. 20), providing a very low-profile fluid circuit construction. Fins 262 extend from a first surface 235 of the heat-sink-and-condenser subassembly 230 (FIGS. 17 and 20). Such integrated construction allows the fins 262 to be comparitively longer than fins in other embodiments, for reasons similar to those described in the discussion of the fins 162b, 162c shown in FIGS. 15 and 16. A second opposing surface 215 (FIG. 18) of the subassembly 230 defines heat transfer surfaces 211, 221 corresponding to the respective microchannel heat sinks 210, 220 and electronic component positions, such that the surfaces 211, 221 can be operatively positioned.

As used herein, “operatively positioned” means located in such a manner (e.g., orientation) so as to be capable of achieving a desired or specified function. For example, an operatively positioned microchannel heat sink can be positioned relative to a corresponding electronic component so as to be capable of thermally coupling to the electronic component, in part, by using conventional thermal interface treatments, such as thermally conductive polymers, greases, composites, adhesives, solders and the like.

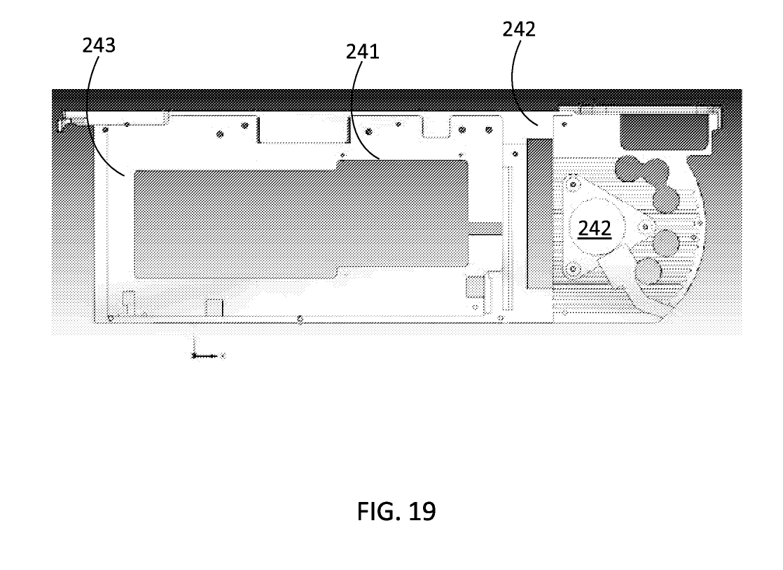

A centrifugal blower 170 is so positioned relative to the fins 262 as to be capable of causing an airstream to pass among the fins (FIG. 17). The pump-housing manifold 255a, 255b, the microchannel heat sink and condenser subassembly 230 (FIG. 20), and the centrifugal blower 170 are supported in respective operative positions by a chassis member 240 (FIGS. 17 and 19). An electric power cable 171 with a power connector extends from an electric motor of the blower 170. A shroud 263 (FIG. 18) comprising features as disclosed above (e.g., a duct extending from the blower 170 and a heat transfer surface overlying the fins 262) can overlie the various components of the cooling system 200. Accordingly, the cooling system 200 can have an external appearance similar to the cooling system 100 as depicted in FIGS. 4A and 4B.

Referring to FIG. 18, heat transfer surfaces 211, 221 defined by the “underside” or second surface 215 of the laminated heat-sink-and-condenser subassembly 230 are visible. The heat transfer surfaces 211, 221 are defined by respective raised surfaces extending from the second surface 215, and each of the surfaces 211, 221 has a generally rectangular perimeter (in some instances, a square perimeter). As best seen in FIG. 21, the respective perimeters of the raised surfaces 211, 221 can be oriented to correspond to an orientation of an electronic package 42, 44 (FIG. 1) when the package is mounted to its respective substrate 46. For example, as shown in FIG. 18, the respective perimeters of the heat transfer surfaces 211, 221 can be rotated by about 45-degrees relative to a longitudinal axis of the cooling system 200 (e.g., relative to, for example, a streamwise axis extending along an airflow path among the various fins 262 (FIG. 17)).

Also visible in FIG. 18 is the chassis member 240, which defines an opening 241. The raised surfaces 211, 221 are sufficiently raised from the surface 215 of the heat sink and condenser subassembly 230 as to extend through the opening 241 and be capable of thermally coupling to (e.g., contacting) respective electronic components 42, 44.

In FIG. 18, an “underside” of the chassis member 240 is visible. By way of reference, a first end region 242 of the chassis member 240 underlies and supports the blower 170 (FIG. 17). An opposing end region of the chassis member 240 defines an exhaust end region 243 underlying an exhaust from the fins 262 (FIG. 17). The “underside” of the cooling system 200 shown in FIGS. 18 and 21 is configured to overlie electronic components of an add-in card 50 (FIG. 4A).

In FIG. 19, a “top side” of the chassis member 240 is shown. The top side of the chassis member 240 shown in FIG. 19 is configured to underlie and to support components of the cooling system 200.

FIG. 20 illustrates the laminated microchannel heat-sink-and-condenser subassembly 230. The subassembly 230 defines an outer perimeter 241′ configured to be received in a corresponding opening 240, recessed portion or both, of the chassis member 240 (FIG. 19) such that the heat transfer surfaces 211, 221 extend through an opening 241 in the chassis member, and the “upper” surface 235 is positioned substantially parallel to, and facing away from, the chassis member. Alignment features, e.g., tabs, can be defined by the perimeter 241′ to aid alignment of the assembly 230 with the chassis member, or tray, 240. Corresponding alignment features of the tray 240 can matingly engage with the alignment features of the assembly 230.

The “upper” surface 235 of the subassembly 230 can be so configured as to be capable of being thermally coupled to a cooler (e.g., a separate heat sink, in a fashion similar to the condenser 130b (FIG. 15), or fins fixedly secured directly to the surface 235, in a fashion similar to the condenser 130c (FIG. 16)). As noted above, providing fins 262 that extend from the condenser surface 235 and eliminating an intervening heat sink base (e.g., by soldering convoluted or stacked fins directly to the surface) can provide for larger fins 262. Stated differently, eliminating components that have a measurable thickness can allow longer fins 262 to be placed within a volume having a limited “height” restriction, such as is imposed by the PCIe Specification. The laminated subassembly 230 provides a low-profile and thin construction that provides additional “height” for the fins 262 (FIG. 17) to occupy.

Referring now to FIG. 22, major surface 215′ of a heat sink plate 230b is shown. The heat sink plate 230b also defines the major surface 215 (FIG. 21) which is on an opposing side of the heat sink plate from the major surface 215′ shown in FIG. 22. As noted above, the major surface 215 defines raised heat transfer surfaces 211, 221 which are configured to thermally couple to respective electronic components. The major surface 215′ of the heat sink plate 230b defines an interior surface of the heat-sink-and-condenser subassembly 230. The major surface 215′ also defines recessed regions 211′, 221′ corresponding to the raised heat transfer surfaces 211, 221, respectively. Stated differently, the surfaces 211 and 211′ are located on opposing faces of, and are separated by a thickness of, the plate 230b. Similarly, the surfaces 221 and 221′ are located on opposing sides of, and are separated by a thickness of, the plate 230b.

As indicated in FIG. 22, the recessed surfaces 211′, 221′ of the plate 230b can receive respective microchannel heat exchangers 210, 220 formed from respective unitary substrates. Each of the heat sinks 210, 220 can be configured as described above. For example, each of the microchannel heat sinks 210, 220 can define high-aspect-ratio microchannels, can define cross-connect channels, or both. A surface of each heat sink's base (not shown, but similar to, for example, the base 123a, 123b (FIGS. 11A through 12B)) can be soldered to (or otherwise fixedly secured and thermally coupled to) the respective recessed surfaces 211′, 221′. The lowermost walls of the microchannels (e.g., a wall of a microchannel 119a, 119b defined by the base 123a, 123b (FIGS. 11A through 12B)) defined by the respective heat sinks 210, 220 can be substantially coplanar with the surface 215′, such that a working fluid can flow over the surface 215′ and into a respective microchannel (e.g., a microchannel 119a (FIG. 11A)) without flowing over a “step”.

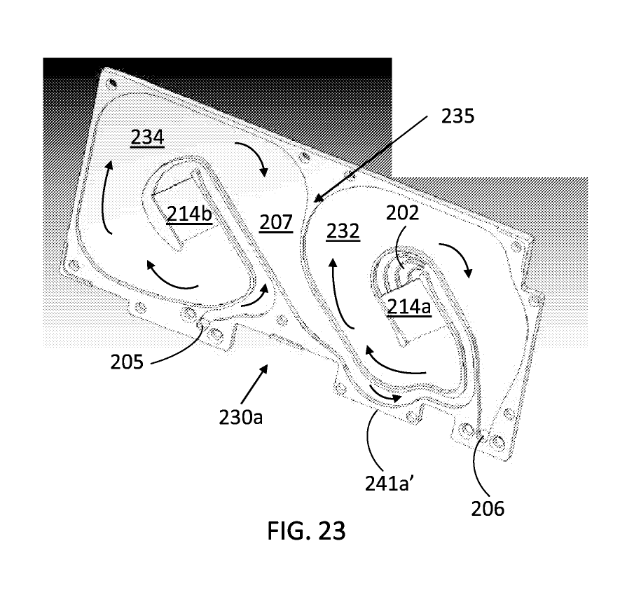

A condenser plate 230a, as shown, for example, in FIGS. 23 and 24, can overlie the heat sink plate 230b in mating engagement therewith to form, for example, the subassembly 230 shown in FIG. 20. Stated differently, the surfaces 215′ (FIG. 22) and 235 (FIG. 23) can be brought into opposing alignment with, and fixedly secured to, each other. For example, an outer perimeter portion 241a′ of the plate 230a (FIG. 22) can be soldered to a corresponding outer perimeter portion 241b′ of the plate 230b (FIG. 21). The condenser plate 230a defines respective lid portions 214a, 214b configured to overlie the respective microchannel heat sinks 210, 220 when the respective microchannel heat sinks 210, 220 are secured to the recessed surfaces 211′, 221′ (FIG. 22). The lid portions 214a, 214b can be recessed portions in the plate 230a and can define an upper wall of the flow microchannels of the respective heat sinks 210, 220, in a fashion similar to the lid 114 shown in the side view of FIG. 10.

The condenser plate 230a defines recessed condenser portions 232, 234 corresponding to the respective lid portions 214a, 214b and microchannel heat sinks 210, 220. In addition, the condenser plate 230a defines an inlet opening 205 and a corresponding recessed conduit portion extending between the opening 205 and the recessed lid portion 214b (corresponding to the heat sink 220). The condenser portion 234 circuitously extends from the recessed lid portion 214b to a recessed conduit portion 207. The recessed conduit portion 207 circuitously extends from the condenser portion 234 to the recessed lid portion 214a. Turning vanes 202 are positioned “upstream” of the lid portion 214a and are configured to function as an inlet manifold to the microchannels defined by the heat sink 210 and the lid portion 214a. The condenser portion 232 corresponding to the heat sink substrate 210 extends from the lid portion 214a to an outlet conduit fluidicly coupled to a condenser plate outlet 206.

As shown in FIG. 24, the condenser plate 230a can define condenser flow channels among extended heat transfer surfaces, or fins 238. The condenser flow channels can measure about 0.635 millimeter (mm) wide and about 2 mm deep, giving the condenser flow channels an aspect ratio, in some instances, of about 3:1 (height:width). In some embodiments, the condenser flow channels can have larger or smaller aspect ratios. The fins defining the condenser flow channels can measure between about 0.25 mm to about 1.0 mm wide (and about 2 mm deep). In addition, the fins 238 can be interrupted at intervals of varying lengths by cross-connect channels 236. As with cross-connect channels described above in connection with microchannel heat exchangers, the cross-connection channels 236 extending among various condenser flow channels can equilibrate pressure variations among adjacent flow channels. Such equilibration of pressure can improve flow uniformity of a working fluid as the fluid rejects heat, changes phase, or both.

With further reference to FIG. 24, the illustrated condenser plate 230a defines a row of fins 238a having a larger cross-sectional thickness than (e.g., about twice) the fins 238. The fins 238a can provide sufficient contact area to solder or otherwise attach respective distal ends of the fins 238a to the heat sink plate 230b (FIG. 22). Such attachment along an approximate centerline of the condenser portions 232, 234 can provide additional stiffness to the subassembly 230, and can mitigate or eliminate any outward bowing, or bulging, that could otherwise occur from high internal pressures that might result when the cooling system 200 is operating.

When the illustrated condenser plate 230a and the illustrated heat sink plate 230b are brought into opposing alignment such that the respective major surfaces 215′, 235′ matingly engage each other, the inlet 205, heat sinks 210, 220 and lid portions 214a, 214b, condenser portions 232, 234, and outlet 206 (and associated conduit portions) are fluidicly coupled in series. In other subassembly embodiments, the heat sinks 210, 220 and condenser portions 232, 234 are fluidicly coupled in parallel.

Such a laminated subassembly 230 as just described provides a thin configuration for a plurality of microchannel heat sinks and condensers. Such a thin subassembly 230 leaves a greater volume for fins 262 than other configurations of microchannel heat sinks and condensers, and thus can allow more surface area for “air side” heat exchange than other configurations.

Referring again to FIG. 17, the subassembly 230 and fins 262 can be supported by the chassis member 240. The outlet 254 of the pump housing manifold 255a, 255b can be fluidicly coupled to the inlet 205 of the subassembly 230. For example, an O-ring can extend around the openings 205, 254 between the pump housing manifold 255a, 255b and the subassembly 230 in a known manner. Similarly, the inlet 256 of the pump housing manifold 255a, 255b can be fluidicly coupled to the outlet 206 from the subassembly 230.

Consequently, the laminated construction of the subassembly 230 in combination with the pump housing manifold 255 provides a very compact two-phase working fluid circuit that leaves significant volume for a large, dense array of fins 262. Such a dense array of fins can reduce, or mitigate, the effects of an “air side” heat exchange “bottleneck,” allowing the cooling system 200 to perform as indicated in the graph shown in FIG. 3. Such a cooling system 200 is well suited for space constrained applications requiring cooling of high heat flux electrical components, such as computer add-in cards, automotive electronics and other applications.

### System Integration

### Example 2

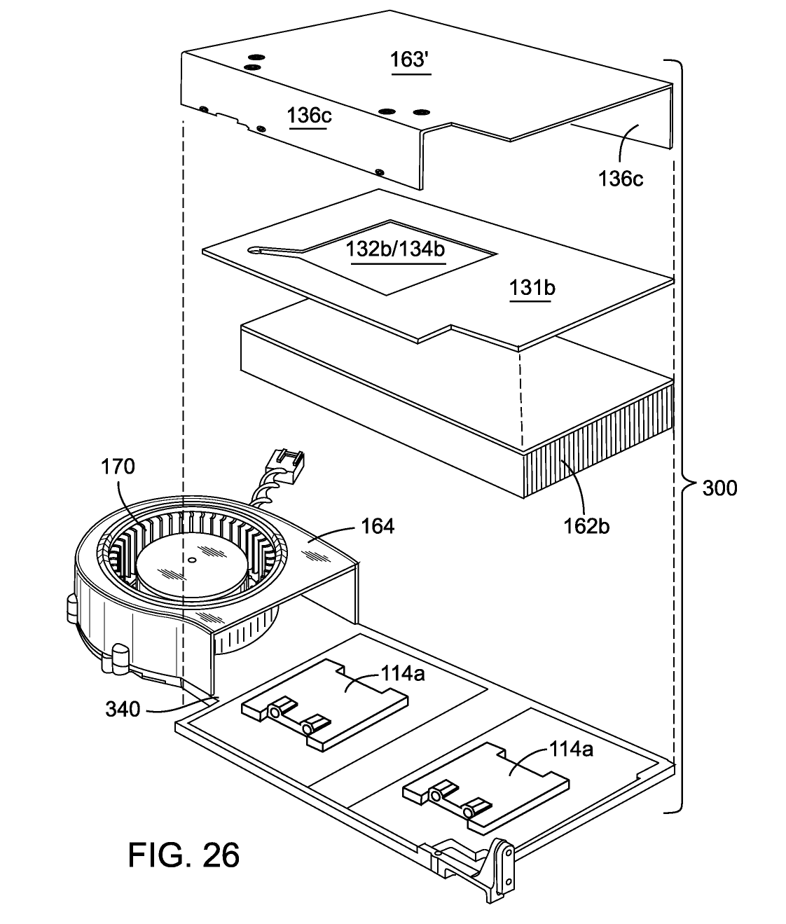

In some systems, each microchannel heat sink can “float” (i.e., move independently of each other) relative to other portions of the cooling system, as described more fully below. Such floating can be desirable when adjacent electronic components have varying heights due to manufacturing tolerances. In other words, each microchannel heat sink 110, 120 can be operatively positioned relative to a corresponding electronic component 42, 44 (FIG. 1) and be positioned throughout a range of positions relative to other portions of the cooling system (e.g., a frame or chassis 340 (FIG. 26)) and each other so as to accommodate dimensional variations among electronic components, substrates and assemblies thereof, that can arise during manufacturing.

The integrated cooling system 300 shown in FIG. 25 will now be described. As with cooling systems described above, the cooling system 300 can be used to remove heat Q₁, Q₂ dissipated by electronic components 42, 44 (FIG. 2) and thereby maintain a specified component temperature at or below an upper threshold temperature.

The cooling system 300 comprises two independently floating microchannel heat sinks 310, 320 supported by the chassis 340 that operatively positions the heat sinks relative to respective electronic components 42, 44, while accommodating variation in z-height among the components.

The chassis 340 is configured to mount and/or support components of the cooling system 300 relative to the substrate 46 (FIG. 1) as well as other cooling system components, such as the heat sink 162c, the condenser 131c, the pump 150′ and the corresponding pump housing-manifold 155′, 155a, 155a′, the blower impeller 170 (and its housing (164)) and the shroud 163′ substantially independently of the floating microchannel heat sinks 310, 320. Such independent mounting allows the heat sinks 310, 320 to remain operatively positioned relative to the respective electronic components 42, 44, as well as the other cooling system components while simultaneously accommodating z-height variation among the components.

As with centrifugal blowers 170 described herein, the illustrated blower impeller can drive an environmental fluid (e.g., air) among extended surfaces 162c of the remote heat exchanger. In the cooling system 300, air passes from a blower inlet to the impeller 170, which imparts a dynamic head to the air. A blower housing 164 defines a diffuser for decelerating the air expelled from the impeller and recovering the dynamic head as pressure head. Such a blower housing usually also defines a blower outlet for connecting to a duct or other conduit 163′ for directing the air emitted by the blower. The shroud, or duct, can define a flow channel between the blower impeller and a flow path among the extended surfaces 162c. In the depicted cooling system 300 (and other cooling systems 100, 200, 400), the impeller rotates clockwise (as viewed from above) such that the airstream emitted from the impeller and blower outlet (not shown) has a higher dynamic head at a region of the heat exchanger inlet (adjacent the blower) furthest from the pump 150′. In other words, in each of the disclosed systems the pump is positioned in a “dead zone” where little or no air flow would occur. In other embodiments, the impeller can rotate counter clockwise, causing the region with the highest dynamic head to be in a region where the pump 150′ is currently shown. In such an embodiment, the pump could be positioned opposite its location in (relative to the heat exchanger), to allow the region with the high dynamic head to fluidicly communication with the heat exchanger fins, and to occupy the “deadzone” where no or little airflow occurs.

In some cooling systems, the blower outlet is matingly engageable with an inlet to the heat exchanger 162c. For example, such a blower housing can matingly engage (e.g., “seamlessly” integrate with) the shroud 163′ formed by the condenser lid, obviating the need for a separate shroud or other piece of ductwork engaging the blower and extending over the remote heat exchanger. Eliminating the separate shroud or other piece of ductwork and its corresponding thickness can allow the remote heat exchanger to have longer extended heat transfer surfaces within a given space-constrained volume.

As applicant discovered, performance of the cooling system 200 can be limited by heat exchange between the heat exchanger 260 and the environment 101 (i.e., “air-side heat exchange”). Applicant also discovered that, surprisingly, eliminating even thin components such as ductwork and the corresponding thickness, and lengthening the extended surfaces (e.g., fins) by a corresponding distance, even just one-tenth of one inch, can improve the air-side heat exchange and significantly improve the cooling capability of cooling systems 100, 200, 300 and 400.

To further increase the available volume for adding fin surface area, the cooling system 300 can comprise a metal shroud portion 163′ configured to transfer a portion Q_{out,2} of the heat Qₒᵤₜ to the environment. The metal shroud portion 163′, as configured in the system 300, is thermally coupled to the condenser. As discussed in connection with FIGS. 15 and 16, the shroud can form a “lid” that partially encloses flow passages within the condenser that carry the working fluid, and thus can be placed in direct contact with the working fluid. Although the illustrated system 300 comprises a metal shroud, in some instances, the shroud 163′ can comprise a plastic shroud extending from the duct 164. In such an embodiment, most of the heat Qₒᵤₜ is rejected from the heat sink 162.

Moreover, the shroud 163′ shown in FIG. 3 comprises a thermally conductive material and is in thermal contact with the condenser 131c so as to provide an additional heat transfer path for rejecting heat absorbed by the cooling system 300 from the electronic components 42, 44 to the environment 101. Applicant discovered that this additional heat transfer path through the shroud can further improve the air-side heat exchange, and substantially increased the overall performance of the cooling system 300.

The chassis 340 defines two primary openings 310′, 320′ (410′, 420′ in FIG. 31) for providing thermal contact between the microchannel heat sinks 310, 320 and corresponding electronic components 42, 44 (FIG. 1). The chassis 240 also defines four leg openings (480a′, 480b′ in FIG. 31) surrounding each of the primary openings 310′, 320′ (410′, 420′ in FIG. 31) through which legs 280 (480a, 480b in FIG. 31) of the microchannel heat sinks 310, 320 (260a, 260b in FIG. 31) can extend, as described above.

With reference to FIGS. 4A, 8C, 25 and 26, a substrate 46 can be positioned in a substantially parallel alignment with and fastened to the chassis 340 with the legs 280 of the microchannel heat sinks 310, 320 extending through the substrate. Once the substrate 46 and chassis 340 are securely attached to each other, the microchannel heat sinks 310, 300 can move relative to the substrate, as they can relative to the chassis. The extent of such movement can depend, in part, on the length and material selected for the fluid conduit 316, 317 joining the microchannel heat sinks 310, 320 to other portions of the cooling system (e.g., the condenser 131c. Nonetheless, the heat sinks 310, 320 can be moved through a sufficient distance so as to operatively position them relative to each respective electronic component 42, 44.

For example, fasteners (not shown) matingly engaging recessed voids of each leg 280 (FIG. 8C) can tighten against the substrate 46 and draw the microchannel heat sinks 310, 320 toward the substrate, urging each microchannel heat sink against a corresponding electronic component 42, 44. In this manner, the microchannel heat sinks can be operatively positioned relative to a corresponding electronic component despite variation in, for example, relative component z-height (Z₁-Z₂) among various add-in cards.

With further reference to FIG. 25, the illustrated heat exchanger 162c is an air-cooled heat sink having a base member comprising a unitary construction with the condenser substrate 131c (FIG. 16) and a plurality of extended heat transfer surfaces (e.g., fins) 162c extending substantially perpendicularly thereto. In some embodiments, the fins are skived fins, and in other embodiments, the fins are stacked fins. The base member 131c is positioned substantially parallel to the chassis 340, and is spaced from the microchannel heat sinks 310, 320 when the system 300 is assembled as indicated in FIG. 25. The plurality of extended heat transfer surfaces 162c extend substantially perpendicularly relative to the base member 131c and downwardly into a space between the base member 131c and the microchannel heat sinks 310, 320. Distal ends of the fins (relative to the base member) are typically adjacent and spaced from the microchannel heat sinks in a normal, at-rest position. Depending, for example, on the extent of z-height variation among electronic components 42, 44, one or more distal ends can be closely positioned adjacent, or even touch, one or both microchannel heat sinks 310, 320 when the cooling system 300 is operatively positioned.

To further increase the available volume for adding fin surface area, the cooling system 300 can comprise a metal shroud portion 163′ configured to transfer a portion Q_{out,2} of the heat Qₒᵤₜ to the environment. The metal shroud portion 163′, as configured in the system 300, is thermally coupled to the condenser. As discussed more fully below, the shroud can form a “lid” that partially encloses flow passages within the condenser that carry the working fluid, and thus can be placed in direct contact with the working fluid. Although the illustrated system 300 comprises a metal shroud, in some instances, the shroud 163′ can comprise a plastic shroud extending from the duct 164. In such an embodiment, most of the heat Qₒᵤₜ is rejected from the heat sink 162.

Referring to FIG. 26, an alternative configuration for the heat sink and condenser is shown. The configuration shown in FIG. 26 is similar to that shown in, and described in connection with, FIG. 15.

### System Integration

### Example 3

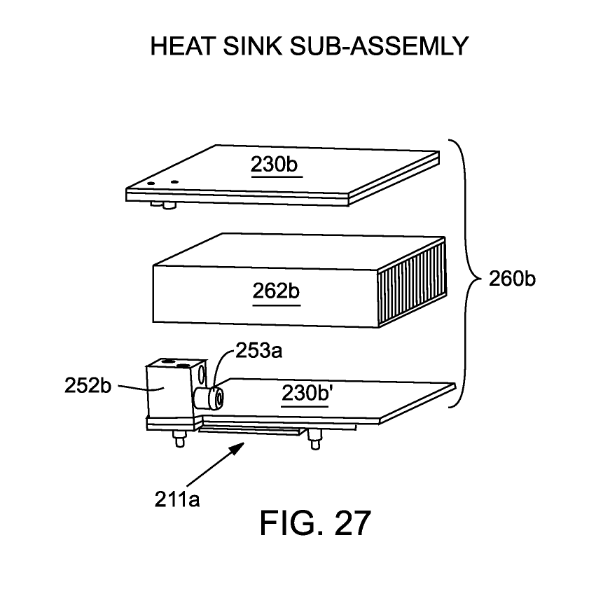

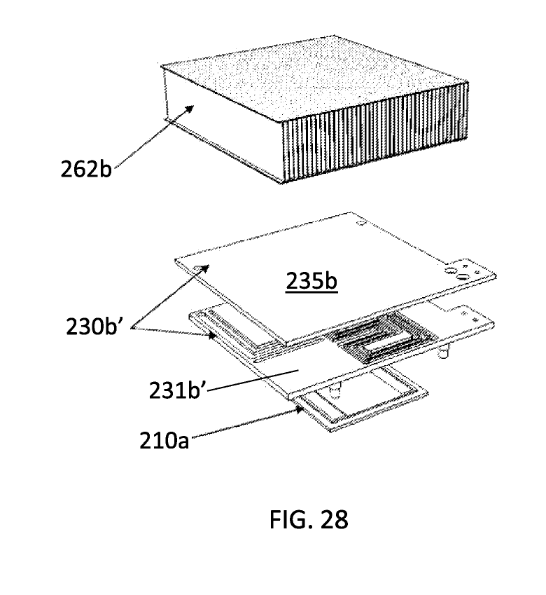

With reference to FIGS. 27 through 31, yet another cooling system 400 will be described. The cooling system 400 (FIG. 31) comprises first and second heat sink subassemblies 260a, 260b. Each of the subassemblies 260a, 260b comprises a respective microchannel heat sink fluidicly coupled to a pair of condenser plates (e.g., plates 230b, 230b′, as shown in FIG. 27 and 231b′ in FIG. 28). As with the systems described above, the subassemblies 260a, 260b can be supported by a chassis member, partially surrounded by a shroud and cooled by a stream of air driven by a blower.

Referring to FIG. 27, a heat sink assembly 260b can comprise a microchannel heat sink substrate as described above. Thus, the microchannel heat sink 210a (FIG. 28) can include cross-connect channels in addition to flow microchannels as described above. The microchannel heat sinks may thus operate as a single-phase (e.g., liquid) heat sink or as two-phase heat sinks, as described above.

The microchannel heat sink 210a can be fluidicly coupled to each of the condenser assemblies 230b, 230b′, and air-cooled fins 262b can extend therebetween. Such a configuration can be particularly useful when airside heat exchange is not the primary system bottleneck. Stated differently, in instances where the fin efficiency of the heat sink fins 262b is low when the fins are heated from a single end (as in the systems 200, 300), placing a second condenser assembly 230b (e.g., surface 235b) in thermal contact with the fins (e.g., in contact with the ends that are distally located from the assembly 230b′) can increase the fin efficiency of the fins 262b and thus dissipate heat at higher rates.

The condenser assemblies 230b, 230b′ have features that are similar to condensers described above. The condenser assemblies can be fluidicly coupled using manifolds as described above and shown in, for example, FIGS. 5 and 6.

FIGS. 27 through 31 depict various features that might be present in embodiments of the heat sink assembly. FIGS. 27 through 31 are not drawn to scale. For simplicity, one or more components of the heat sink assembly may be omitted from one or more of FIGS. 27 through 31. As shown, the heat sink assembly may include one or more heat sink subassemblies (sub-assemblies) 260a, 260b, as well as at least one pump and blower. For simplicity, one pump 250a and one blower are shown. However, in other embodiments, multiple pumps and/or multiple blowers might be used. Also for simplicity, two sub-assemblies are shown. However, another number of sub-assemblies may be used. For example, a single sub-assembly, or three or more sub-assemblies, might be employed.

In addition, the sub-assemblies are shown as being substantially similar (FIGS. FIGS. 27 through 31). However, in some embodiments, portions or all of each of the sub-assemblies may differ. For example, the plates of the sub-assembly 260b may be larger than heat that of sub-assembly 260a. The respective microchannel heat sinks 210a, 210b can also be different among the sub-assemblies. For each sub-assembly, two plates having fins coupled there between are used. However, in another embodiment, another number of plates which may, or may not, utilize the same configuration of fins might also be employed. The assembly may be coupled with electrical component(s) desired to be cooled. Such electrical components are not shown. For example, in some embodiments, the assemblies might be used to cool a graphics card.

With reference to FIG. 27, each sub-assembly includes, by way of example, a microchannel heat sink 210a, a bottom plate 230b′, a top plate 230b, fins 262b, and at least one manifold 252b. Heat is exchanged from the device being cooled to the microchannel heat sink Heat from the microchannel heat sink is exchanged with the bottom and top plates of each sub-assembly. Heat from the bottom and top plates is also provided to the air stream generated by the blower through the use of two cooling plates with internal cooling passages (i.e. fins). Thus, heat from the component being cooled may be removed from the system.

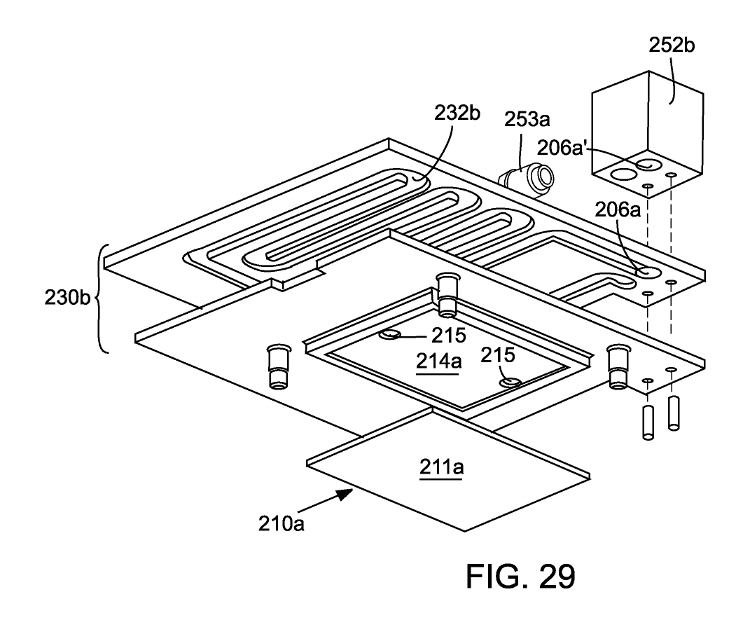

With reference to FIGS. 5, 6 and 29, in general, fluid that may be saturated enters the microchannel heat sink 210a. In one embodiment, fluid flows from the pump 250a, through manifold 252b to the bottom plate 230b (through openings 206a and 206a′), through an inlet or outlet coupler 215 (FIG. 29), then to the microchannel heat sink 210a. The fluid flows through the micro sized passages in the heat sink and absorbs heat. The fluid may change phase (boil) if sufficient heat is exchanged and/or a sufficiently low flow is used. A two-phase fluid can exit the microchannel heat sink 210a and goes into the channels 232b of the bottom cooling plate 230b. In the bottom plate 230b, one or more fluid channels 232b are arranged in a pattern, such as a serpentine pattern. The channels 232b may cover the area of the bottom plate 230b. This allows the hot fluid to spread the heat over the area of the bottom plate. In one embodiment, heat may be spread substantially over the entire bottom plate, creating a larger platform area than the die (microchannel heat sink) size to transfer heat to the air. The heat conducts up into the air heat exchange fins, then to the air flowing through the assembly. From the bottom plate 230b, the fluid travels to the top cooling plate 230b′ (FIG. 27). In one embodiment, fluid travels from the bottom plate 230b to the top plate 230b′ via the manifold 252b. Fluid traverses channel(s) in the top plate. Heat may be spread in an analogous manner to the bottom plate 230b. Although the fluid flow is described as traversing the sub-assemblies in series, the heat sink assembly might be configured so that the sub-assemblies are fluidicly coupled in parallel.

As the fluid travels through the top and bottom cooling plates and the heat is rejected to the air, a vapor condenses and a saturated fluid, or slightly sub-cooled fluid, leaves the top plate 230b′. The fluid flows from the top plate 230b′ of the sub-assembly 260b to the bottom plate 230a of the sub-assembly 260a. In one embodiment, the manifold 252b conveys fluid from the top plate to a cross-over tube 258 or other mechanism for providing fluid to the sub-assembly 260a. In another embodiment, the fluid may be passed to another pump, which then pumps the fluid to the sub-assembly 260a. The fluid then travels from the bottom plate 230a′ into the inlet of the microchannel heat sink 220. Here the fluid may follow an analogous (including identical) path as the sub-assembly 260b. The sub-assembly 260a functions in a similar manner to the sub-assembly 260b. The fluid can transfer heat into the air heat exchange fins 262a, 262b as well as to a shroud 463 (FIG. 31) to reject heat to the areas right outside of the cooling system 400. Upon exiting the top plate 230a, the fluid is then sent back to the pump 250a.

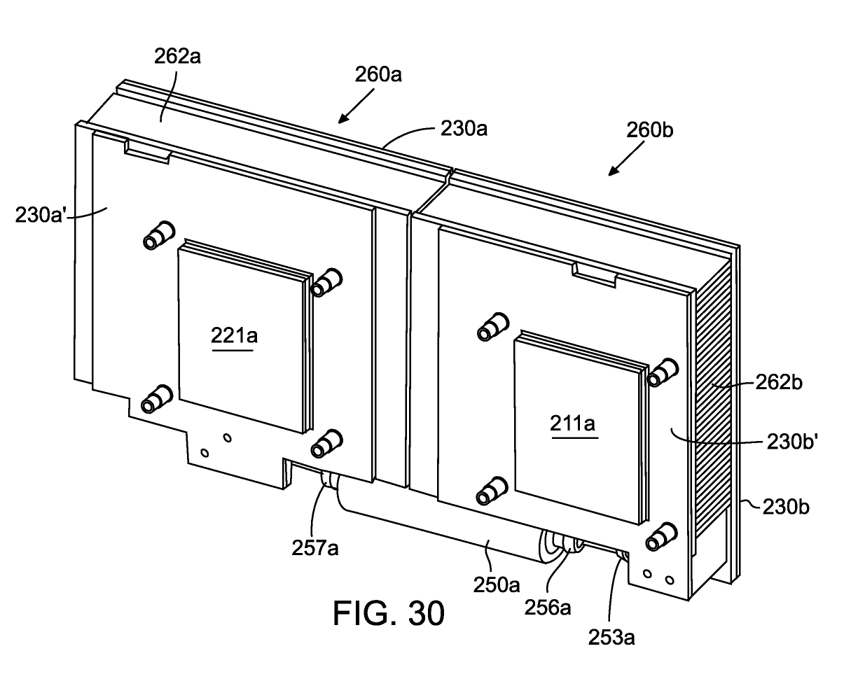

Such heat sink assemblies 260a, 260b as shown in FIG. 30 can provide a variety of advantages as with the systems 100, 200 and 300. Phase change can occur without a substantial temperature gradient within the fluid changing phase. An advantage of using boiling heat transfer for cooling applications can include providing a uniform temperature at which to provide the cooling. The temperature may be uniform with regards to the boiling surface as well as a changing heat input. Thus, the component to be cooled by the assembly may have a more uniform temperature. Further, as the latent heat of vaporization of a fluid is high in comparison to a change in temperature of the fluid, a greater amount of heat might be able to be dissipated using microchannel heat sinks.

As with other systems described above, the heat sink assemblies 260a, 260b can be configured as counterflow heat exchangers (e.g., a general flow direction of the working fluid runs counter to a general flow direction of the environmental fluid, e.g., air, through the heat exchanger fins extending between the condenser plate assemblies).

In addition, each sub-assembly includes two plates with fins there between. Use of two plates doubles the contact surface area for heat transfer between the fluids and fins. Further, each fin is attached to both the top and bottom plate. This allows the heat to be transferred into the fins from both ends of the fins. Heat transfer from both ends, effectively reduces the fin length for each conduction heat transfer path. This improves the fin efficiency, which is inversely related to the fin length. Stated differently, cooling at the ends of fins is avoided because both of the fin ends are all attached to a plate.

Further, the location of the pump may be selected to improve the efficiency of the heat sink assembly. As discussed above, the air flow direction is generally from the sub-assembly 260a to the sub-assembly 260b. However, in some embodiments, the airflow may have some transverse component to its direction of motion. Air flow from the blower does not flow uniformly and linearly from the blower. Instead, the circular motion of the blower impeller imparts an air flow direction that is not completely parallel to the passages formed by the fins 262b. As a result, a region in the heat sink assembly may have a lower air flow. Stated differently, a dead zone may exist in the air flow. The pump is located in the sink assembly's dead zone. Because the pump, which does not require a direct exchange of heat to the air flow to function as desired, is located in this dead zone, regions of the heat sink assembly which do maintain an airflow may remain available for use in exchanging heat. Consequently, efficiency of the heat sink assembly may be improved.

Further, use of manifolds may also improve the heat sink assembly. The heat sink sub-assemblies may utilize manifolds for directing fluid entering and leaving the top and bottom plates, as well as entering and leaving the sub-assembly. The manifold is solid, for example formed from a copper block having holes drilled therein to control fluid flow. In some embodiments, a manifold directs fluid entering a sub-assembly to the bottom plate, directs fluid from the bottom plate to the top plate and directs fluid from the top plate to a cross-over tube to another sub-assembly or back to the pump. The manifolds may be used in lieu of tubing to direct the fluid flow. As such issues such as leakage, lack of stability, and increasing the footprint of the system, may be avoided. Further, because the manifold may be a large copper block, the manifold may provide a larger footprint to solder to the bottom plate or remaining portions of the sub-assembly. Thus, the manifold may also improve stability, reduce leakage, and otherwise improve the performance of the heat sink assembly.

The heat sink assembly may also have improved cooling efficiency through the use of dummy channels. The bottom plate can include a dummy channel and channels to and from the microchannel heat sink Note that the specific configuration of the channels and dummy channel may vary. Further, additional channels and/or additional dummy channels may be provided in another embodiment. The dummy channel may be used to insulate fluid entering the microchannel heat sink In one embodiment, the dummy channel is formed in the bottom plate. When a cover is provided on the bottom plate, an air-filled dummy channel is formed. Alternatively, the cover could be provided in another atmosphere and sealed, or the channel might be filled another way. Fluid enters the microchannel heat sink from the bottom plate of the sub-assembly. This fluid is comparatively cold. Fluid leaving the microchannel heat sink traverses the bottom plate. Fluid from the microchannel heat sink is relatively hot, having just received heat from the microchannel heat sink The dummy channels may be filled with air, other thermal insulator(s), or vacuum. As a result, the dummy channels are thermally insulative. Because the dummy channel is insulative in nature, the dummy channel may assist in thermally isolating the channel into the microchannel heat sink Consequently, fluid to the microchannel heat sink may remain cooler. The efficiency of the microchannel heat sink may thereby be improved.

Heat sink assemblies described herein may share some or all of the benefits discussed above. For example, the heat sink assemblies may employ one or more of the following: microchannel heat sinks, liquid flow in a counter direction to air flow, multiple cooling plates each of which are connected with fins, pump(s) in a dead zone for air flow, manifolds, and/or dummy channels. Thus, the assemblies may have improved efficiency, improved stability, improved cooling, and/or other benefits previously described.

As shown in FIG. 31, the heat sink assemblies 260a, 260b can be fluidicly coupled to each other and supported by a chassis member 440 similar to the chassis members described above. The chassis member 440 can support the blower 170 and a shroud 464 can overlie the blower 170, and a duct 463 can overlie the respective heat sink assemblies 260a, 260b. Thermal contact surfaces 211a, 221a can extend through the chassis member (openings 410′ and 420′) sufficiently to be thermally coupled to a component mounted to, for example, an add-in card.

### Microscale Heat Transfer System Performance

FIG. 32 shows test data obtained from a working sample of a closed-circuit cooling loop having a two-phase flow through a microchannel heat sink as disclosed herein. The inlet pressure Pin and the outlet pressure Pout shown in FIG. 32 vary much less than if the flow field through the microchannel heat sink was unstable. Accordingly, the substantially uniform inlet pressure and outlet pressure shown in FIG. 32 indicates that the two-phase flow through the microchannel heat sink remains stable, despite the relatively high-heat flux that would cause a flow through a microchannel heat sink having continuous fins (i.e., without cross-connections, as disclosed herein) to be unstable. The data shown in FIG. 32 demonstrates the surprising enhancement in heat sink performance attained by including the cross-connections, compared to a microchannel heat sink without the cross-connections.

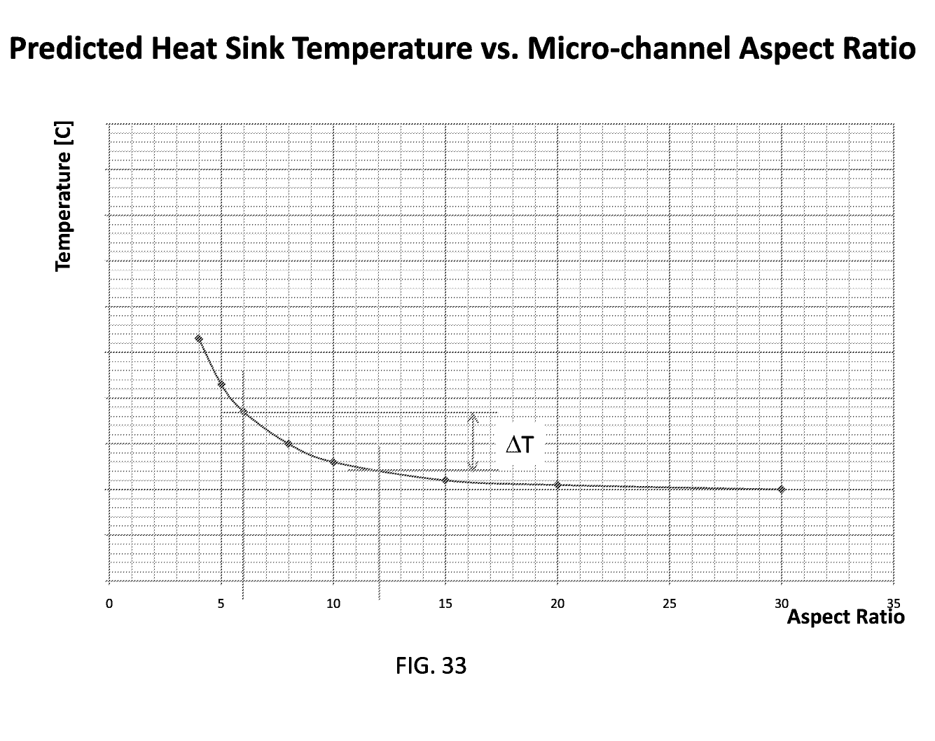

FIG. 33 shows a graph of predicted heat sink temperature variation with microchannel aspect ratio. FIG. 33 indicates that, for the assumed cooling system and environmental conditions, doubling the microchannel aspect ratio from 6:1 to 12:1 was predicted to decrease the heat sink temperature rise above ambient, ΔT, by about 1.2 degrees Celsius (° C.) when dissipating about 150 Watts (W).

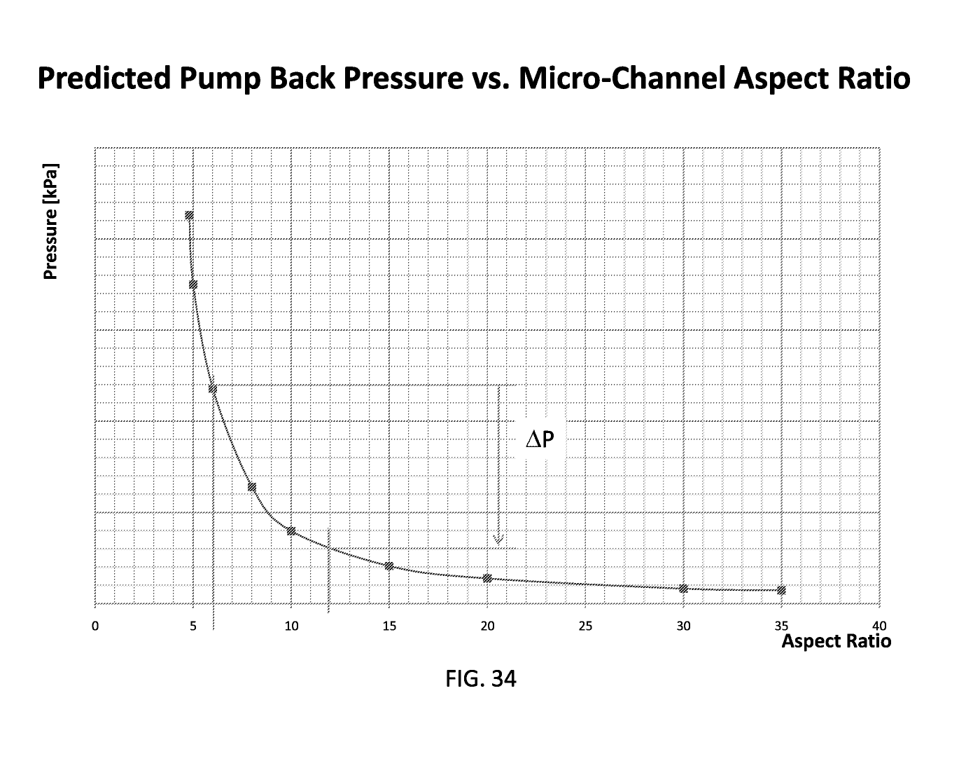

FIG. 34 shows a graph of predicted pump back pressure variation with microchannel aspect ratio. FIG. 16 indicates that, for the assumed cooling system and environmental conditions, doubling the microchannel aspect ratio from 6:1 to 12:1 was predicted to decrease the pump back pressure ΔP by a factor of about 4:1.

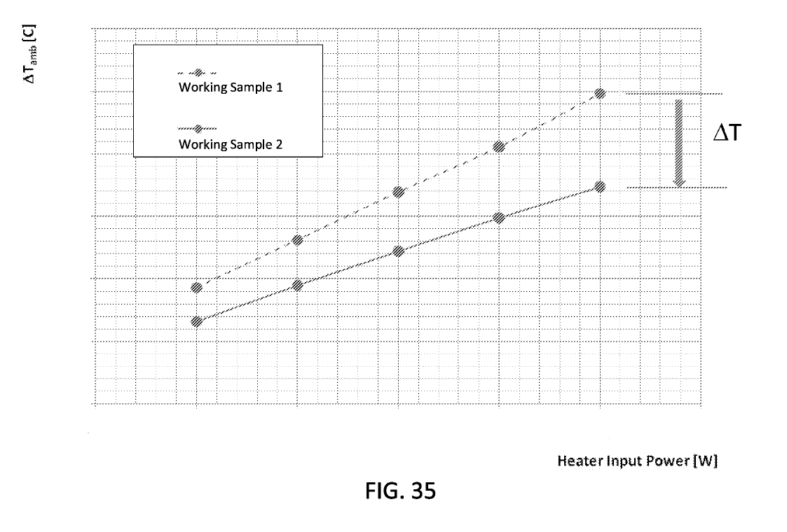

FIG. 35 shows a comparison plot of microchannel heat sink temperature rise above ambient temperature for a microchannel heat sink defining cross-connected microchannels with an aspect ratio of 6:1 (Working Sample 1) and a working microchannel heat sink defining high aspect ratio (12:1) and cross-connected microchannels (Working Sample 2), as disclosed herein. As shown in FIG. 35, under a 150 W cooling load, the heat sink having 12:1 aspect ratio microchannels provided a surprising 7.4° C. lower temperature rise above ambient temperature than the heat sink having 6:1 aspect ratio microchannels. This 7.4° C. improvement demonstrates surprisingly better performance than predicted (e.g., much better than the predicted 1.2° C. improvement indicated in FIG. 33).

### OTHER EMBODIMENTS

With the described features, it is possible in many embodiments to cool electrical components dissipating as much as 150 Watts (continuously) with as little as about 30° C.-35° C. component temperature rise above a local environmental temperature with a cooling system that fits within a small, compact volume (e.g., a volume compatible with the PCIe specification and measuring about 10½ inches by about 1⅜ inches by about 3¾.

This disclosure makes reference to the accompanying drawings which form a part hereof, wherein like numerals designate like parts throughout. The drawings illustrate specific embodiments, but other embodiments may be formed and structural changes may be made without departing from the intended scope of this disclosure. Directions and references (e.g., up, down, top, bottom, left, right, rearward, forward, etc.) may be used to facilitate discussion of the drawings but are not intended to be limiting. For example, certain terms may be used such as “up,” “down,”, “upper,” “lower,” “horizontal,” “vertical,” “left,” “right,” and the like. These terms are used, where applicable, to provide some clarity of description when dealing with relative relationships, particularly with respect to the illustrated embodiments. Such terms are not, however, intended to imply absolute relationships, positions, and/or orientations. For example, with respect to an object, an “upper” surface can become a “lower” surface simply by turning the object over. Nevertheless, it is still the same surface and the object remains the same. As used herein, “and/or” means “and” as well as “and” and “or.”

Accordingly, this detailed description shall not be construed in a limiting sense, and following a review of this disclosure, those of ordinary skill in the art will appreciate the wide variety of cooling systems that can be devised and constructed using the various concepts described herein. Moreover, those of ordinary skill in the art will appreciate that the exemplary embodiments disclosed herein can be adapted to various configurations without departing from the disclosed concepts. Thus, in view of the many possible embodiments to which the disclosed principles can be applied, it should be recognized that the above-described embodiments are only examples and should not be taken as limiting in scope. We therefore claim as our invention all that comes within the scope and spirit of the following claims.

1. A microscale heat transfer system comprising:
a microchannel heat exchanger defining a plurality of flow microchannels fluidicly coupled to each other by a plurality of cross-connect channels spaced apart along a streamwise flow direction defined by the flow microchannels such that the microchannel heat exchanger is configured to stably vaporize a portion of a working fluid when the microchannel heat exchanger is thermally coupled to a heat source;
a condenser fluidicly coupled to the microchannel heat exchanger and configured to condense the vaporized portion of the working fluid; and
a pump so fluidicly coupled to the condenser and the microchannel heat exchanger as to be configured to circulate the working fluid between the microchannel heat exchanger and the condenser.

2. The microscale heat transfer system of claim 1, wherein the microchannel heat exchanger and the condenser comprise portions of an integrated subassembly comprising:
a first plate defining opposed internal and external major surfaces, wherein the internal major surface of the first plate defines a heat sink region configured to receive the microchannel heat exchanger; and
a second plate defining opposed internal and external major surfaces, wherein the internal major surface of the second plate defines a lid region and a condenser region,
wherein the first plate and the second plate are fixedly secured together in opposing alignment such that the respective internal major surfaces face each other, and wherein the microchannel heat exchanger is disposed between the first plate and the second plate.

3. The microscale heat transfer system of claim 2, wherein the microchannel heat exchanger is thermally coupled to the heat sink region, and wherein the lid region so overlies the plurality of flow microchannels as to define a flow boundary of the flow microchannels.

4. The microscale heat transfer system of claim 3, wherein the condenser region of the second plate and a corresponding, opposed region of the first plate define at least one condenser flow channel.

5. The microscale heat transfer system of claim 4, wherein the condenser region of the second plate defines a plurality of fins extending from the internal major surface of the second plate and being spaced from each other along a streamwise flow direction defined the at least one condenser flow channel.

6. The microscale heat transfer system of claim 5, wherein at least one of the plurality of extended surfaces is soldered to a corresponding portion of the internal surface of the first plate.

7. The microscale heat transfer system of claim 2, wherein the integrated subassembly further comprises a plurality of fins extending from the external major surface of the first plate, the second plate, or both.

8. The microscale heat transfer system of claim 2, wherein the external major surface of the first plate defines a raised surface positioned substantially opposite the heat sink region defined by the internal major surface of the first plate.

9. The microscale heat transfer system of claim 2, wherein the microchannel heat exchanger comprises a first microchannel heat exchanger and a second microchannel heat exchanger, and wherein the heat sink region comprises a first heat sink region and a second heat sink region, wherein the first heat sink region is configured to receive the first microchannel heat sink and the second heat sink region is configured to receive the second microchannel heat sink.

10. The microscale heat transfer system of claim 9, wherein the lid region comprises a first lid region and a second lid region, wherein the first lid region overlies the first heat exchanger and the second lid region overlies the second microchannel heat exchanger.

11. The microscale heat transfer system of claim 9, wherein the condenser region comprises a first condenser region and a second condenser region.

12. The microscale heat transfer system of claim 11, wherein the first microchannel heat sink and the first condenser region are fluidicly coupled to the second microchannel heat sink and the second condenser region in series.

13. The microscale heat transfer system of claim 11, wherein the first microchannel heat sink and the first condenser region are fluidicly coupled to the second microchannel heat sink and the second condenser region in parallel.

14. The microscale heat transfer system of claim 2, further comprising a pump housing manifold defining an internal chamber configured to receive the pump, an inlet opening and an outlet opening, wherein the pump is positioned at least partially within the internal chamber of the pump housing manifold.

15. The microscale heat transfer system of claim 14, wherein the pump defines a pump inlet and a pump outlet, wherein the pump inlet is fluidicly coupled to the inlet opening of the pump housing manifold and the pump outlet is fluidicly coupled to the outlet opening of the pump housing manifold.

16. The microscale heat transfer system of claim 1, wherein a flow cross-section of one or more of the flow microchannels defines an aspect ratio greater than about 10:1.

17. An add-in card for a computer system, the add-in card comprising:
a substrate comprising a plurality of circuit portions;
at least one integrated circuit component electrically coupled to at least one of the circuit portions, wherein the integrated circuit component dissipates heat when operating;
a working fluid;
an evaporator positioned adjacent and thermally coupled to the integrated circuit component, wherein the evaporator defines a plurality of cross-connected microchannels configured to stably vaporize a portion of the working fluid in response to heat dissipated by the component;
a condenser fluidicly coupled to the evaporator, wherein the condenser is supported, at least in part, by the substrate;
a pump so fluidicly coupled to the evaporator and to the condenser as to be operable to circulate the working fluid between the evaporator and the condenser

18. The add-in card of claim 17, wherein the condenser and the evaporator comprise portions of an integrated subassembly comprising opposing first and second plates, wherein the evaporator comprises a microchannel heat sink disposed between the first and second plates.

19. The add-in card of claim 18, wherein the integrated subassembly further comprises a plurality of fins extending outwardly of the first plate, the second plate, or both.

20. The add-in card of claim 18, wherein the evaporator comprises a first evaporator and a second evaporator.

21.-22. (canceled)

23. The add-in card of claim 17, wherein the condenser further comprises a plurality of fins extending outwardly thereof, wherein the add-in card further comprises a shroud overlying the fins and a blower configured to deliver air over the fins, wherein the evaporator, the condenser, the pump, the fins and the blower fit within a 10½ inch, by 1⅜ inch, by 3¾ inch volume, when the evaporator, the condenser, the pump the fins and the blower are operatively positioned relative to each other and the integrated circuit component.

24. (canceled)

25. The add-in card of claim 17, further comprising a chassis member overlying and engaging at least a portion of the substrate, wherein the condenser is fixedly attached to the chassis member such that the chassis supports the condenser, whereby the condenser is at least partially supported by the substrate.

26.-31. (canceled)
